(19) United States
(12) Patent Application Publication
(10) Pub. No.: US 2024/0405178 A1
(43) Pub. Date: Dec. 5, 2024

(54) DISPLAY DEVICE AND METHOD OF FABRICATING THE SAME

(71) Applicant: Samsung Display Co., LTD., Yongin-si (KR)

(72) Inventors: Yu Jin LEE, Yongin-si (KR); Hui Won YANG, Yongin-si (KR); Sun PARK, Yongin-si (KR)

(21) Appl. No.: 18/673,002

(22) Filed: May 23, 2024

(30) Foreign Application Priority Data
Jun. 2, 2023 (KR) 10-2023-0071880

(51) Int. Cl. H01L 33/62; H01L 25/075; H01L 25/16; H01L 33/38

(52) U.S. Cl. CPC H01L 33/62; H01L 25/0753; H01L 25/167; H01L 33/38; H01L 2933/0016; H01L 2933/0066

(57) ABSTRACT

A display device may include: a substrate having a display area and a non-display area, and including a first surface and a second surface facing away from each other in a thickness direction of the substrate, and a side surface connecting the first and second surfaces; a light emitting element on the first surface of the substrate in the display area; a pad electrode on the first surface of the substrate in the non-display area; an intermediate electrode on the second surface of the substrate in the display area; and a side connection line on the side surface, and electrically connected to each of the pad electrode and the intermediate electrode. The pad electrode may include a first pad electrode and a second pad electrode. Opposite side surfaces of the second pad electrode may have the same inclination angles as opposite side surfaces of the first pad electrode.

### CROSS-REFERENCE TO RELATED APPLICATION

The present application claims priority to and the benefit of Korean Patent Application No. 10-2023-0071880, filed on Jun. 2, 2023, in the Korean Intellectual Property Office, the entire disclosure of which is incorporated by reference herein.

### BACKGROUND

### 1. Field

Various embodiments of the present disclosure relate to a display device and a method of fabricating the display device.

### 2. Description of Related Art

Recently, as interest in information display increases, research and development on display devices have been continuously conducted.

### SUMMARY

Various embodiments of the present disclosure may provide a display device and a method of fabricating the display device with improved fabrication efficiency and reliability.

One or more embodiments of the present disclosure may provide a display device, including: a substrate having a display area and a non-display area, and including a first surface and a second surface facing away from each other in a thickness direction of the substrate, and a side surface connecting the first surface and the second surface; a light emitting element on the first surface of the substrate in the display area; a pad electrode on the first surface of the substrate in the non-display area; an intermediate electrode on the second surface of the substrate in the display area; and a side connection line on the side surface, and electrically connected to each of the pad electrode and the intermediate electrode. The pad electrode may include a first pad electrode and a second pad electrode that are successively stacked. Opposite side surfaces of the second pad electrode may have inclination angles that are same as inclination angles of opposite side surfaces of the first pad electrode.

In one or more embodiments, the first pad electrode may include an opaque conductive material, and the second pad electrode may include a transparent conductive material.

In one or more embodiments, the display device may further include: a first pixel circuit layer on the first surface of the substrate; a display element layer on the first pixel circuit layer; and a second pixel circuit layer on the second surface of the substrate. The pad electrode may be on the first pixel circuit layer.

In one or more embodiments, the display element layer may include: a first electrode and a second electrode on the first pixel circuit layer in the display area and spaced from each other; and the light emitting element electrically connected to the first electrode and the second electrode.

In one or more embodiments, each of the first electrode and the second electrode may include a lower electrode and an upper electrode that are successively stacked. The lower electrode may be in a same layer as the first pad electrode, and the upper electrode may be in a same layer as the second pad electrode.

In one or more embodiments, the lower electrode may include a same material as the first pad electrode, and the upper electrode may include a same material as the second pad electrode.

In one or more embodiments, opposite side surfaces of the upper electrodes of the first electrode and the second electrode may have inclination angles that are same as inclination angles of opposite side surfaces of the corresponding lower electrodes of the first electrode and the second electrode.

In one or more embodiments, the display element layer may further include an anisotropic conductive film located between each of the first and second electrodes and the light emitting element, and configured to electrically connect the first electrode to one side of the light emitting element, and electrically connect the second electrode to a remaining side of the light emitting element.

In one or more embodiments, the first pixel circuit layer may further include: a transistor electrically connected to the light emitting element; and a light blocking pattern between the substrate and a semiconductor pattern of the transistor.

In one or more embodiments, the second pixel circuit layer may include: a first insulating layer on the second surface of the substrate; a connection electrode on the first insulating layer; a via layer on the first insulating layer and the connection electrode, and allowing a portion of the connection electrode to be exposed; and a second insulating layer on the via layer.

In one or more embodiments, the connection electrode may include a first connection electrode and a second connection electrode stacked successively from the first insulating layer. The first connection electrode may include an opaque conductive material, and the second connection electrode may include a transparent conductive material.

In one or more embodiments, the display device may further include an overcoat layer on the side connection line and the pad electrode, and covering the side connection line and the pad electrode.

In one or more embodiments, the light emitting element may include a micro light emitting diode.

One or more embodiments of the present disclosure may provide a method of fabricating a display device, including: forming a first pixel circuit layer including a front pattern on a first surface of a substrate; forming, on the first pixel circuit layer, a pad electrode, a first electrode, and a second electrode that are spaced from each other; forming a second pixel circuit layer including a rear pattern on a second surface of the substrate; forming a side connection line on a side surface of the substrate; and transferring a light emitting element on the first electrode and the second electrode, and electrically connecting the light emitting element to each of the first and the second electrodes. The pad electrode may include a first pad electrode and a second pad electrode stacked successively on the first pixel circuit layer. Opposite side surfaces of the second pad electrode may have inclination angles that are same as to inclination angles of opposite side surfaces of the first pad electrode.

In one or more embodiments, forming the pad electrode may include: applying a first base layer for the first pad electrode on the first pixel circuit layer, applying a second base layer for the second pad electrode on the first base layer, and applying a photosensitive material layer on the second base layer; disposing a mask over the photosensitive material layer and forming a photosensitive pattern covering one area of the second base layer and exposing a remaining area of the second base layer; performing a first etching process to remove the exposed remaining area of the second base layer and exposing the first base layer located thereunder; performing a second etching process and removing the exposed first base layer; and removing the photosensitive pattern and exposing the one area of the second base layer under the photosensitive pattern and one area of the first base layer under the one area of the second base layer.

In one or more embodiments, the first etching process may include a wet etching process, and the second etching process may include a dry etching process.

In one or more embodiments, the first base layer may include an opaque conductive material, and the second base layer may include a transparent conductive material. The one area of the second base layer may include the second pad electrode, and the one area of the first base layer may include the first pad electrode.

In one or more embodiments, each of the first electrode and the second electrode may include a lower electrode and an upper electrode successively stacked on the first pixel circuit layer. The lower electrode may be formed through a same process as the first pad electrode, and the upper electrode may be formed through a same process as the second pad electrode.

In one or more embodiments, opposite side surfaces of the upper electrodes of the first electrode and the second electrode may have inclination angles that are same as inclination angles of opposite side surfaces of the lower electrodes of the first electrode and the second electrode.

In one or more embodiments, the light emitting element may include a micro light emitting diode.

### BRIEF DESCRIPTION OF THE DRAWINGS

FIG. 1 is a schematic perspective view illustrating a tiled display device in accordance with one or more embodiments.

FIG. 2 is a schematic plan view illustrating the tiled display device of FIG. 1 in accordance with one or more embodiments.

FIG. 3 is a schematic enlarged view showing a portion EA1 of FIG. 1.

FIG. 4 is a schematic plan view illustrating a display device in accordance with one or more embodiments.

FIG. 5 is a schematic cross-sectional view illustrating a display device in accordance with one or more embodiments.

FIG. 6 is a schematic flowchart illustrating a method of fabricating the display device of FIG. 4.

FIG. 7 is a schematic plan view illustrating the pixel of FIG. 4.

FIG. 8 is a schematic cross-sectional view taken along the line I-I′ of FIG. 7.

FIG. 9 is a schematic enlarged view showing a portion EA2 of FIG. 2.

FIGS. 10 and 11 are schematic cross-sectional views taken along the line II-II′ of FIG. 9.

FIGS. 12-18 are schematic cross-sectional views illustrating a method of forming a pad electrode, a first electrode, and a second electrode of FIG. 10.

### DETAILED DESCRIPTION

As the present disclosure allows for various changes and numerous embodiments, particular embodiments will be illustrated in the drawings and described in detail in the written description. However, this is not intended to limit the present disclosure to particular modes of practice, and it is to be appreciated that all changes, equivalents, and substitutes that do not depart from the technical scope of the present disclosure are encompassed in the present disclosure.

Throughout the present disclosure, like reference numerals refer to like parts throughout the various figures and embodiments of the present disclosure. The sizes of elements in the accompanying drawings may be exaggerated for clarity of illustration. It will be understood that, although the terms “first”, “second”, etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

It will be further understood that the terms “comprise”, “include”, “have”, etc. when used in this specification, specify the presence of stated features, integers, steps, operations, elements, components, and/or combinations of them but do not preclude the presence or addition of one or more other features, integers, steps, operations, elements, components, and/or combinations thereof. Furthermore, in case that a first part such as a layer, a film, a region, or a plate is disposed on a second part, the first part may be not only directly on the second part but a third part may intervene between them. In addition, in case that it is expressed that a first part such as a layer, a film, a region, or a plate is formed on a second part, the surface of the second part on which the first part is formed is not limited to an upper surface of the second part but may include other surfaces such as a side surface or a lower surface of the second part. To the contrary, in case that a first part such as a layer, a film, a region, or a plate is under a second part, the first part may be not only directly under the second part but a third part may intervene between them.

Embodiments of the present disclosure are described with reference to the accompanying drawings in order to describe the present disclosure in detail so that those having ordinary knowledge in the technical field to which the present disclosure pertains can easily practice the present disclosure. Furthermore, a singular form may include a plural form as long as it is not specifically mentioned in a sentence.

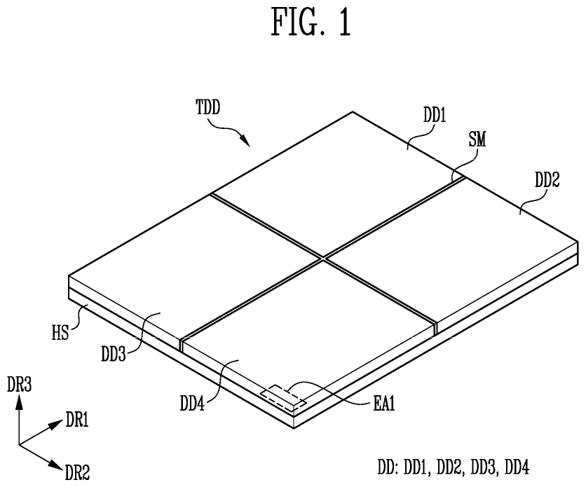

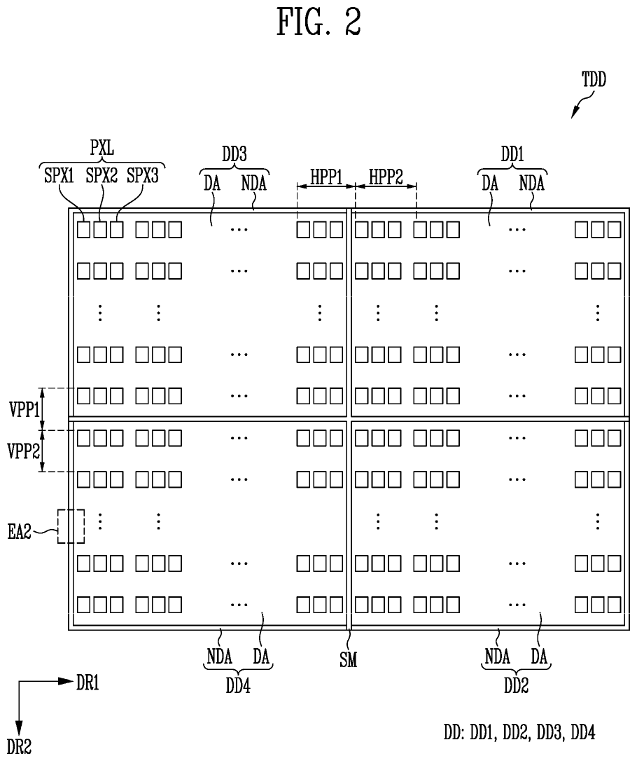

FIG. 1 is a schematic perspective view illustrating a tiled display device TDD in accordance with one or more embodiments. FIG. 2 is a schematic plan view illustrating the tiled display device TDD in accordance with one or more embodiments.

Referring to FIGS. 1 and 2, the tiled display device TDD may embody a multi-screen display device including a plurality of display devices DD.

If the display devices DD may be used for an electronic device having a display surface on at least one surface thereof, e.g., a smartphone, a television, a tablet PC, a mobile phone, a video phone, an electronic reader, a desktop PC, a laptop PC, a netbook computer, a workstation, a server, a PDA, a portable multimedia player (PMP), an MP3 player, a medical appliance, a camera, or a wearable device, the embodiments of the present disclosure may be applied to the electronic device.

The tiled display device TDD may include a plurality of display devices DD arranged in a matrix shape in a first direction DR1 and a second direction DR2 (e.g., arranged along rows and columns of a matrix), and a housing HS.

The plurality of display devices DD may respectively display individual images or partitively display one image. The plurality of display devices DD may include, for example, a first display device DD1, a second display device DD2, a third display device DD3, and a fourth display device DD4.

The first to fourth display devices DD1, DD2, DD3, and DD4 may be arranged parallel to each other in such a way that respective display surfaces (or image display surfaces) provided to display images are oriented in one direction. The first to fourth display devices DD1, DD2, DD3, and DD4 may have the same size (or the same surface area), but the present disclosure is not limited thereto. In one or more embodiments, each of the first to fourth display devices DD1, DD2, DD3, and DD4 may have a size (or a surface area) different from that of adjacent display devices DD to meet design conditions or the like of the tiled display device TDD to be applied.

Each of the first to fourth display devices DD1, DD2, DD3, and DD4 may be provided in various forms, for example, in the form of a rectangular plate having two pairs of parallel sides, but the present disclosure is not limited thereto.

The first to fourth display devices DD1, DD2, DD3, and DD4 may be arranged in a matrix form (e.g., arranged along rows and columns of a matrix). The matrix form may include at least one row and at least two columns.

The housing HS may physically couple the first to fourth display devices DD1, DD2, DD3, and DD4 to each other to allow the first to fourth display devices DD1, DD2, DD3, and DD4 to form a single tiled display device TDD. The housing HS may be disposed on certain surfaces (or lower surfaces) of the first to fourth display devices DD1, DD2, DD3, and DD4 to control or fix the movement of the first to fourth display devices DD1, DD2, DD3, and DD4. Each of the first to fourth display devices DD1, DD2, DD3, and DD4 may be detachably fastened to the housing HS by at least one fastener. As a result, each of the first to fourth display devices DD1, DD2, DD3, and DD4 can be easily detached from or attached to the housing HS, thus allowing for convenient repair in case of any defect occurring in one of the first to fourth display devices DD1, DD2, DD3, and DD4.

The first to fourth display devices DD1, DD2, DD3, and DD4 may have a substantially similar or identical structure. For example, each of the first to fourth display devices DD1, DD2, DD3, and DD4 may include a display area DA and a non-display area NDA. The display area DA may include a plurality of pixels PXL to display an image. Each of the pixels PXL may include first to third sub-pixels SPX1, SPX2, and SPX3.

Each of the first to third sub-pixels SPX1, SPX2, and SPX3 may include at least one of an organic light emitting diode (LED) including an organic emission layer, a quantum dot LED including a quantum dot emission layer, an inorganic LED including an inorganic semiconductor, and a micro LED. For example, each of the first to third sub-pixels SPX1, SPX2, and SPX3 may include a micro LED.

Each of the first to third sub-pixels SPX1, SPX2, and SPX3 may emit light having a certain peak wavelength through an emission area. The emission area may be an area where light generated from the light emitting element disposed in the display device DD is emitted out of the display area DD. The first sub-pixel SPX1 may emit a first color of light. The second sub-pixel SPX2 may emit a second color of light. The third sub-pixel SPX3 may emit a third color of light. For example, the first color of light may be red light having a peak wavelength ranging from 610 nm to 650 nm. The second color of light may be green light having a peak wavelength ranging from 510 nm to 550 nm. The third color of light may be blue light having a peak wavelength ranging from 440 nm to 480 nm, but the present disclosure is not limited thereto.

The first to third sub-pixels SPX1, SPX2, and SPX3 may be sequentially and repeatedly arranged along the first direction DR1 of the display area DA. The surface areas of the respective emission areas of the first to third sub-pixels SPX1, SPX2, and SPX3 may be substantially the same as each other, but the present disclosure is not limited thereto. In one or more embodiments, the surface area (or the size) of the emission area of the third sub-pixel SPX3 may be greater than the surface of the emission area of the first sub-pixel SPX1, and the surface area of the emission area of the first sub-pixel SPX1 may be greater than the surface area of the emission area of the second sub-pixel SPX2, but the present disclosure is not limited thereto.

The non-display area NDA may be disposed around the display area DA to enclose the display area DA, and may not display any image.

The tiled display device TDD may have an overall planar shape, but the present disclosure is not limited thereto. The tiled display device TDD may have a three-dimensional shape, thus providing a three-dimensional effect to a user. For example, in the case where the tiled display device TDD has a three-dimensional shape, at least some display devices DD from among the plurality of display devices DD may have a curved shape. As another example, each of the display devices DD may have a planar shape, and the display devices DD may be connected to each other at specific angles, thus allowing the tiled display device TDD to have a three-dimensional shape.

The tiled display device TDD may include a seam area SM disposed between the display areas DA. The tiled display device TDD may be formed by connecting the respective non-display areas NDA of adjacent display devices DD to each other. The display devices DD may be connected to each other by a fastener, an adhesive, or the like provided in the seam area SM. The seam area SM of each of the display devices DD may include neither a pad component nor a flexible film attached to the pad component. The distance between the display areas DA of each of the display devices DD may be sufficiently close such that the seam areas SM between the display devices DD are not perceptible to the user. For example, a first horizontal pixel pitch HPP1 between the pixels PXL of the first display device DD1 and the pixels PXL of the third display device DD3 may be substantially the same as a second horizontal pixel pitch HPP2 between the pixels PXL of the first display device DD1. A first vertical pixel pitch VPP1 between the pixels PXL of the third display device DD3 and the pixels PXL of the fourth display device DD4 may be substantially the same as a second horizontal pixel pitch VPP2 between the pixels PXL of the fourth display device DD4. Therefore, the tiled display device TDD may improve the sense of continuity between the display devices DD and enhance the immersion of images by preventing the seam areas SM between the display devices DD from being perceived by the user.

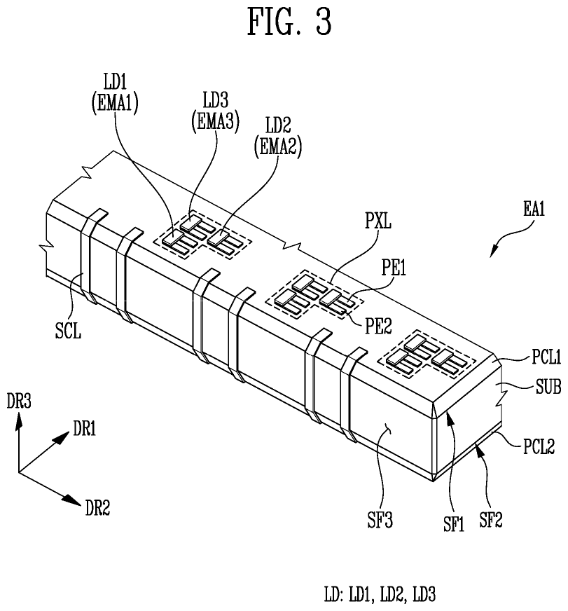

FIG. 3 is a schematic enlarged view illustrating a portion EA1 of FIG. 1.

Referring to FIGS. 1 to 3, the fourth display device DD4 (or the display device DD) may include a substrate SUB, a first pixel circuit layer PCL1, a second pixel circuit layer PCL2, and a light emitting element LD.

The substrate SUB may include a first surface SF1 (e.g., a front surface or an upper surface) and a second surface SF2 (e.g., a rear surface or a lower surface) that are opposite each other in a third direction DR3 (or in a thickness direction of the substrate SUB). Furthermore, the substrate SUB may include a side surface SF3 (or an edge area), which connects the first surface SF1 and the second surface SF2. The side surface SF3 (or the edge area) may be an outermost portion of the substrate SUB.

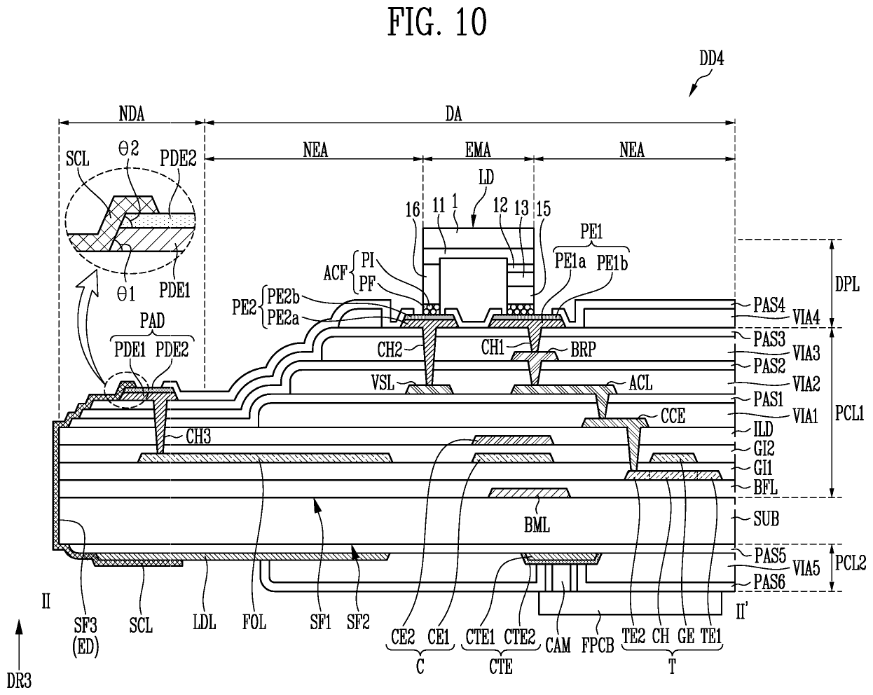

In the side surface SF3, a plurality of side connection lines SCL may be disposed at positions that are spaced from each other at regular intervals. Each of the side connection lines SCL may electrically connect a pad electrode (refer to “PAD” of FIG. 10) formed on the first pixel circuit layer PCL1 with one of rear patterns of the second pixel circuit layer PCL2, e.g., a lead line (refer to “LDL” of FIG. 10). A first end of the side connection line SCL may be electrically connected to the pad electrode PAD. A second end of the side connection line SCL may be electrically connected to the lead line LDL.

The first pixel circuit layer PCL1 may be disposed on the first surface SF1 of the substrate SUB. A first electrode PE1 and a second electrode PE2 that are spaced from each other may be disposed on the first pixel circuit layer PCL1. Furthermore, light emitting elements LD electrically connected to the first and second electrodes PE1 and PE2 may be disposed on the first pixel circuit layer PCL1. In one or more embodiments, the first electrode PE1 may be an anode, and the second electrode PE2 may be a cathode.

The light emitting elements LD may include a first light emitting element LD1, a second light emitting element LD2, and a third light emitting element LD3. The first light emitting element LD1 may be disposed in the first sub-pixel SPX1 of the pixel PXL. The second light emitting element LD2 may be disposed in the second sub-pixel SPX2 of the pixel PXL. The third light emitting element LD3 may be disposed in the third sub-pixel SPX3 of the pixel PXL. An area where light is emitted from the first sub-pixel SPX1 may be a first emission area EMA1. An area where light is emitted from the second sub-pixel SPX2 may be a second emission area EMA2. An area where light is emitted from the third sub-pixel SPX3 may be a third emission area EMA3.

The first pixel circuit layer PCL1 may include front patterns electrically connected to the light emitting elements LD, and one or more insulating layers disposed between the front patterns. The front patterns may include, for example, a transistor, a signal line, and the like.

The second pixel circuit layer PCL2 may be disposed on the second surface SF2 of the substrate SUB. The second pixel circuit layer PCL2 may include rear patterns configured to electrically connect the transistor disposed in the first pixel circuit layer PCL1 to an external driver, and one or more insulating layers disposed between the rear patterns.

The fourth display device DD4 (or the display device DD) having the aforementioned configuration is provided with the side connection line SCL, thus reducing or minimizing the non-display area NDA on the first surface SF1 of the substrate SUB and increasing or maximizing the display area DD, thereby enabling a bezel-less design, and increasing the mounting density of the light emitting elements LD. As such, the tiled display device TDD, which is configured by connecting a plurality of display devices DD having a bezel-less design may implement a large display area DA capable of displaying images without making the seam area SM between the display devices DD perceptible to the user.

In one or more embodiments, a corner formed on the side surface SF3 included in the non-display area NDA of the substrate SUB may be chamfered to form a chamfer surface having a certain angle.

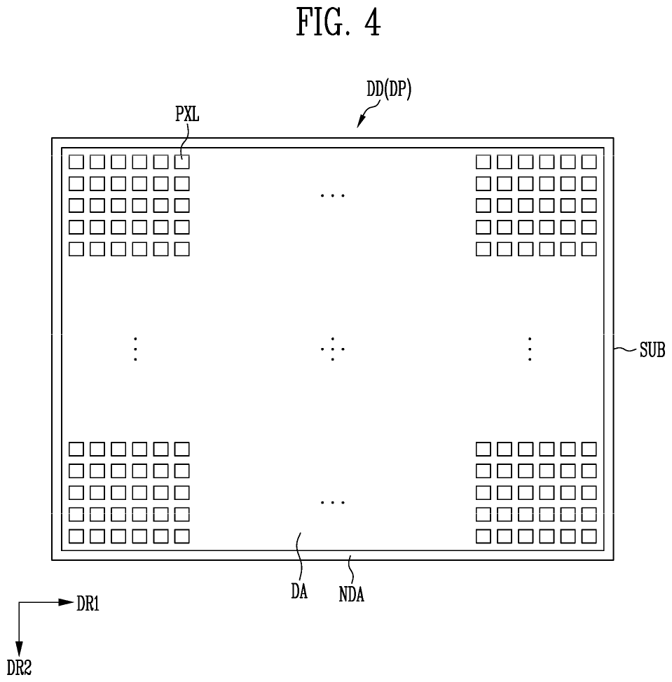

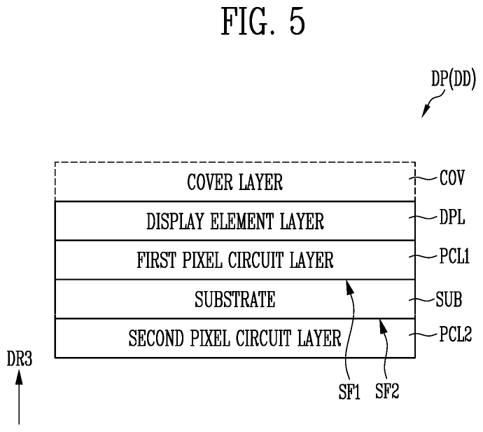

FIG. 4 is a schematic plan view illustrating a display device DD in accordance with one or more embodiments. FIG. 5 is a schematic cross-sectional view illustrating the display device DD in accordance with one or more embodiments.

In FIGS. 4 and 5, for the convenience sake, there is schematically illustrated the display device DD, for example, the structure of a display panel DP provided in the display device DD, centered on a display area DA in which an image is displayed.

Referring to FIGS. 1 to 5, the display panel DP (or the display device DD) may include a substrate SUB, and pixels PXL disposed in a display area DA.

The substrate SUB may be provided as one area having an approximately rectangular shape. However, the number of areas provided in the substrate SUB may be changed. The shape of the substrate SUB may be changed depending on areas provided in the substrate SUB. The substrate SUB may include a first surface SF1 and a second surface SF2 that are opposite each other in the third direction DR3.

The substrate SUB may include one or more insulating materials such as glass or resin. Furthermore, the substrate SUB may include one or more materials having flexibility so as to be bendable or foldable, and may have a single-layer structure or a multilayer structure. For instance, examples of the material having flexibility may include at least one of the following: polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate. However, the material constituting the substrate SUB is not limited to that of the foregoing embodiments. In one or more embodiments, the substrate SUB may be formed of a glass material.

The substrate SUB (or the display panel DP) may include a display area DA and a non-display area NDA. The display area DA may be an area in which the pixels PXL are provided to display an image. The non-display area NDA may be an area in which the pixels PXL are not provided, and may be an area in which an image is not displayed. The non-display area NDA may be disposed around the display area DA along an edge or periphery of the display area DA. For example, the non-display area NDA may enclose at least a portion of the display area DA.

The pixels PXL may be disposed in the display area DA of the substrate SUB. The pixels PXL each may include a light emitting element configured to emit color light. Each of the pixels PXL may emit light of any one color from among red, green, and blue, and it is not limited thereto.

The pixels PXL may be arranged in the form of a matrix in the first direction DR1 and the second direction DR2, but the present disclosure is not limited thereto.

The display panel DP (or the display device DD) may include a first pixel circuit layer PCL1 disposed on the first surface SF1 of the substrate SUB, a display element layer DPL disposed on the first pixel circuit layer PCL1, a second pixel circuit layer PCL2 disposed on the second surface SF2 of the substrate SUB. Furthermore, the display panel DP may selectively further include a cover layer COV disposed on the display element layer DPL.

The first pixel circuit layer PCL1 may include front patterns including transistors and signal lines, and one or more insulating layers may be disposed between the front patterns.

The display element layer DPL may be disposed on the first pixel circuit layer PCL1. The display element layer DPL may include a first electrode PE1 and a second electrode PE2 electrically connected to the front patterns, and light emitting elements LD electrically connected to the first and second electrodes PE1 and PE2.

The cover layer COV may be provided to cover the display element layer DPL, thus protecting the display element layer DPL from external impacts. The cover layer COV may prevent the seam area SM between adjacent display devices DD from being visible to the user, and absorb light incident on the seam area SM or light reflected from the seam area SM, thus reducing or minimizing the perception of the seam area SM. In one or more embodiments, the cover layer COV may be omitted.

The second pixel circuit layer PCL2 may be disposed on the second surface SF2 of the substrate SUB. Rear patterns may be disposed in the second pixel circuit layer PCL2. The rear patterns may electrically connect the transistors of the first pixel circuit layer PCL1 to an external driver. Disposed between the rear patterns, at least one or more insulating layers may be provided in the second pixel circuit layer PCL2.

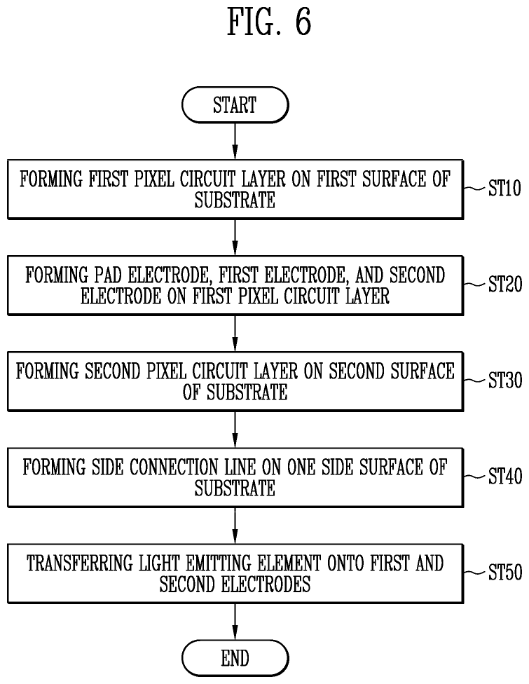

FIG. 6 is a schematic flowchart illustrating a method of fabricating the display device DD of FIG. 4.

Referring to FIGS. 4 to 6, the first pixel circuit layer PCL1 may be formed on the first surface SF1 of the substrate SUB (at step ST10).

At the aforementioned step, the front patterns including the transistors and the signal lines, and the one or more insulating layers disposed between the front patterns may be formed on the first surface SF1 of the substrate SUB.

The pad electrode (refer to “PAD” of FIG. 10), the first electrode (refer to “PE1” of FIG. 3), and the second electrode (refer to “PE2” of FIG. 3) are formed on the first pixel circuit layer PCL1 (at step ST20).

The pad electrode PAD may be positioned in the non-display area NDA of the display device DD. The first electrode PE1 and the second electrode PE2 may be positioned in the display area DA of the display device DD.

The substrate SUB is turned upside down so that the second surface SF2 of the substrate SUB is oriented upward, and the second pixel circuit layer PCL2 is formed on the second surface SF2 of the substrate SUB (at step ST30).

At the aforementioned step, the rear patterns electrically connected to the front patterns, and one or more insulating layers disposed between the rear patterns may be formed on the second surface SF2 of the substrate SUB.

The substrate SUB is turned upside down such that the first surface SF1 of the substrate SUB is oriented upward, and the side connection line SCL is thereafter formed on the side surface (refer to “SF3” of FIG. 3) of the substrate SUB (at step ST40).

The first end of the side connection line SCL may extend to an upper surface of the pad electrode PAD on the first surface SF1 of the substrate SUB and may be electrically connected to the pad electrode PAD. The second end of the side connection line SCL may extend to a portion of the rear pattern, for example, an upper surface of the lead line LDL of FIG. 10, on the second surface SF2 of the substrate SUB, and may be electrically connected to the lead line LDL. Due to the side connection line SCL, the pad electrode PAD positioned on the first surface SF1 of the substrate SUB and the rear pattern positioned on the second surface SF2 of the substrate SUB may be electrically connected to each other.

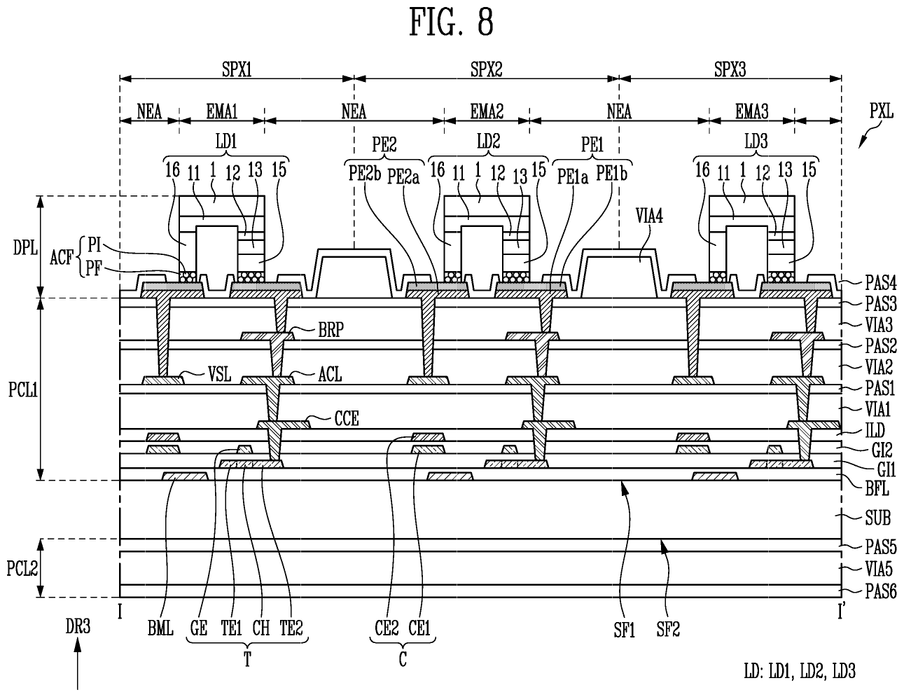

A plurality of light emitting elements (refer to “LD” of FIG. 8) arranged on a transfer substrate are transferred onto the first electrode PE1 and the second electrode PE2 (at step ST50).

The display device DD in accordance with one or more embodiments may be fabricated through the aforementioned fabrication process. Hereinafter, the configuration of the pixel PXL included in the display device DD will be described.

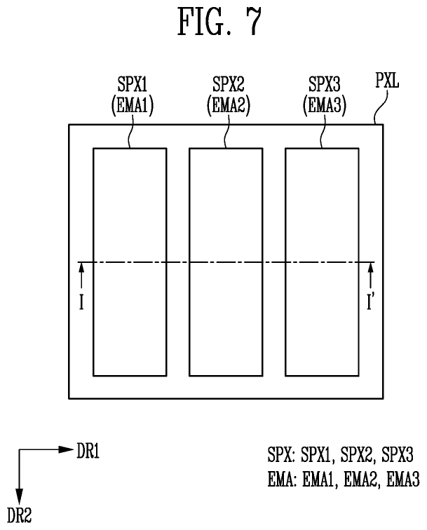

FIG. 7 is a schematic plan view illustrating the pixel PXL of FIG. 4. FIG. 8 is a schematic cross-sectional view taken along the line I-I′ of FIG. 7.

The description with reference to FIGS. 7 and 8 will be focused on differences from the above-mentioned embodiments so as to avoid redundant description.

Referring to FIGS. 4 to 8, the pixel PXL may include a plurality of sub-pixels SPX. For example, the pixel PXL may include a first sub-pixel SPX1, a second sub-pixel SPX2, and a third sub-pixel SPX3. Although FIG. 7 illustrates that each pixel PXL includes three sub-pixels SPX, the present disclosure is not limited thereto.

Each of the first sub-pixel SPX1, the second sub-pixel SPX2, and the third sub-pixel SPX3 may have a rectangular shape, a square shape, or a rhombus shape, in a plan view, but the present disclosure is not limited thereto. The first sub-pixel SPX1, the second sub-pixel SPX2, and the third sub-pixel SPX3 may be arranged in the first direction DR1. Alternatively, two sub-pixels from among the first, second, and third sub-pixels SPX1, SPX2, and SPX3 may be arranged side by side in the first direction DR1, and the other one sub-pixel may be disposed on a pixel row subsequent to that of the two sub-pixels in the second direction DR2. The arrangement form of the sub-pixels SPX is not limited to the aforementioned embodiment.

The first sub-pixel SPX1 may emit a first color of light. The second sub-pixel SPX2 may emit a second color of light. The third sub-pixel SPX3 may emit a third color of light. For example, the first color of light may correspond to light in a red wavelength band. The second color of light may correspond to light in a green wavelength band. The third color of light may correspond to light in a blue wavelength band.

Light emitting elements LD may be included in the sub-pixels SPX and disposed in emission areas EMA. The light emitting elements LD may include a first light emitting element LD1, a second light emitting element LD2, and a third light emitting element LD3. The first light emitting element LD1 may be disposed in the emission area EMA of the first sub-pixel SPX1. The second light emitting element LD2 may be disposed in the emission area EMA of the second sub-pixel SPX2. The third light emitting element LD3 may be disposed in the emission area EMA of the third sub-pixel SPX3. For example, the first light emitting element LD1 may be disposed in the first emission area EMA1. The second light emitting element LD2 may be disposed in the second emission area EMA2. The third light emitting element LD3 may be disposed in the third emission area EMA3.

The pixel PXL may include a substrate SUB, a first pixel circuit layer PCL1, a display element layer DPL, and a second pixel circuit layer PCL2.

The substrate SUB may be a base substrate or a base component. The substrate SUB may be a flexible substrate which is bendable, foldable, rollable, and/or the like. For example, the substrate SUB may include an insulating material, e.g., polymer resin such as polyimide (PI), but is not limited thereto. In one or more embodiments, the substrate SUB may be a rigid substrate including a glass material.

The substrate SUB may include a first surface SF1 and a second surface SF2 that are opposite each other in the third direction DR3. The first pixel circuit layer PCL1 may be disposed on the first surface SF1, and the second pixel circuit layer PCL2 may be disposed on the second surface SF2. The first surface SF1 may be the upper surface (or the front surface) of the substrate SUB, and the second surface SF2 may be the lower surface (or the back surface) of the substrate SUB.

The first pixel circuit layer PCL1 and the display element layer DPL may be disposed on the first surface SF1 of the substrate SUB and overlap each other. For example, the sub-pixel SPX may include the first pixel circuit layer PCL1 disposed on the first surface SF1 of the substrate SUB, and the display element layer DPL disposed on the first pixel circuit layer PCL1.

Front patterns may be disposed in the first pixel circuit layer PCL1. For example, at least one transistor T and signal lines electrically connected to the transistor T may be disposed in the first pixel circuit layer PCL1. The first pixel circuit layer PCL1 may include at least one insulating layer disposed on the first surface SF1 of the substrate SUB. For example, the insulating layer may include a buffer layer BFL, a first gate insulating layer GI1, a second gate insulating layer GI2, an interlayer insulating layer ILD, a first via layer VIA1, a first passivation layer PAS1, a second via layer VIA2, a second passivation layer PAS2, a third via layer VIA3, and a third passivation layer PAS3, which are successively stacked on the first surface SF1 of the substrate SUB in the third direction DR3 (or in the thickness direction of the substrate SUB).

The buffer layer BFL may be disposed on the overall surface of the first surface SF1 of the substrate SUB. The buffer layer BFL may prevent impurities from diffusing into the transistor T. The buffer layer BFL may be an inorganic insulating layer including inorganic material. The buffer layer BFL may include at least one of silicon nitride (SiNₓ), silicon oxide (SiOₓ), silicon oxynitride (SiOₓN_{y}), and/or aluminum oxide (AlOₓ). The buffer layer BFL may be provided in the form of a single layer structure, or provided in the form of a multilayer structure having at least two or more layers. In case that the buffer layer BFL is provided in the form of a multilayer structure, the respective layers may be formed of the same material or different materials. The buffer layer BFL may be omitted depending on the material of the substrate SUB or processing conditions.

The first gate insulating layer GI1 may be disposed on the overall surface of the buffer layer BFL. The first gate insulating layer GI1 may include the same material as that of the buffer layer BFL, or include a suitable material from among the materials exemplified as the constituent materials of the buffer layer BFL. For example, the first gate insulating layer GI1 may be an inorganic insulating layer including an inorganic material.

The second gate insulating layer GI2 may be disposed on the overall surface of the first gate insulating layer GI1. For example, the second gate insulating layer GI2 may be an inorganic insulating layer including an inorganic material.

The interlayer insulating layer ILD may be provided and/or formed on the overall surface of the second gate insulating layer GI2. The interlayer insulating layer ILD may include the same material as that of the buffer layer BFL, or include a suitable material selected from among the materials exemplified as the constituent materials of the buffer layer BFL.

The first via layer VIA1 may be provided and/or formed on the overall surface of the interlayer insulating layer ILD. The first via layer VIA1 may be an inorganic insulating layer including an inorganic material or an organic insulating layer including an organic material. The inorganic insulating layer may include, for example, at least one of silicon oxide (SiOₓ), silicon nitride (SiNₓ), silicon oxynitride (SiOₓN_{y}), and/or aluminum oxide (AlOₓ). The organic insulating layer may include, for example, at least one of polyacrylic resin, epoxy resin, phenolic resin, polyamide resin, polyimide rein, unsaturated polyester resin, poly-phenylen ether resin, poly-phenylene sulfide resin, and/or benzocyclobutene resin. In one or more embodiments, the first via layer VIA1 may have an even surface to reduce a step difference caused by components disposed thereunder. In one or more embodiments, the first via layer VIA1 may include an organic insulating layer including an organic material.

The first passivation layer PAS1 may be provided and/or formed on the overall surface of the first via layer VIA1. The first passivation layer PAS1 may be an inorganic insulating layer including an inorganic material. The first passivation layer PAS1 may include at least one of silicon nitride (SiNₓ), silicon oxide (SiOₓ), silicon oxynitride (SiOₓN_{y}), and/or aluminum oxide (AlOₓ).

The second via layer VIA2 may be provided and/or formed on the overall surface of the first passivation layer PAS1. The second via layer VIA2 may include the same material as that of the first via layer VIA1, or may include a suitable material selected from among the materials exemplified as the constituent material of the first via layer VIA1. For example, the second via layer VIA2 may be formed of an organic insulating layer including an organic material.

The second passivation layer PAS2 may be provided and/or formed on the overall surface of the second via layer VIA2. The second passivation layer PAS2 may include the same material as the first passivation layer PAS1. The second passivation layer PAS2 may be an inorganic insulating layer including an inorganic material.

The third via layer VIA3 may be provided and/or formed on the overall surface of the second passivation layer PAS2. The third via layer VIA3 may include the same material as the first via layer VIA1. For example, the third via layer VIA3 may be formed of an organic insulating layer including an organic material.

The third passivation layer PAS3 may be provided and/or formed on the overall surface of the third via layer VIA3. The third passivation layer PAS3 may include the same material as the first passivation layer PAS1. The third passivation layer PAS3 may be an inorganic insulating layer including an inorganic material.

Each of the first via layer VIA1, the second via layer VIA2, and the third via layer VIA3 may be used as a planarization layer for mitigating a step difference caused by components disposed thereunder.

The first pixel circuit layer PCL1 may include at least one or more conductive layers disposed between the above-mentioned insulating layers. For example, the first pixel circuit layer PCL1 may include a first conductive layer disposed between the substrate SUB and the buffer layer BFL, a second conductive layer disposed between the first gate insulating layer GI1 and the second gate insulating layer GI2, a third conductive layer disposed between the second gate insulating layer GI2 and the interlayer insulating layer ILD, a fourth conductive layer disposed between the interlayer insulating layer ILD and the first via layer VIA1, a fifth conductive layer disposed between the first passivation layer PAS1 and the second via layer VIA2, and a sixth conductive layer disposed between the second passivation layer PAS2 and the third via layer VIA3.

The first conductive layer may have a single-layer structure formed of one or a combination selected from the group consisting of copper, molybdenum, tungsten, neodymium, titanium, aluminum, silver, and/or an alloy thereof. Furthermore, the first conductive layer may be implemented as a double-layer or multi-layer structure formed of molybdenum, titanium, copper, aluminum, and/or silver, which is a low resistance material, so as to reduce the line resistance. Each of the second to sixth conductive layers may include the same material as the first conductive layer, or include a suitable material selected from among the materials exemplified as the constituent material of the first conductive layer, but the present disclosure is not limited thereto.

The first pixel circuit layer PCL1 may include a transistor T, and a plurality of electrodes and lines that are electrically connected to the transistor T. For example, the first pixel circuit layer PCL1 may include a bottom metal pattern BML, the transistor T, a capacitor C, a power line VSL, a connection electrode CCE, an anode connection line ACL, and a bridge pattern BRP, but the present disclosure is not limited thereto.

The bottom metal pattern BML may block light from being drawn from the second surface SF2 of the substrate SUB into certain components of the front pattern. The bottom metal pattern BML may correspond to the first conductive layer disposed between the substrate SUB and the buffer layer BFL. The bottom metal pattern BML may be formed of molybdenum, but is not limited thereto.

The transistor T may include a semiconductor pattern and a gate electrode GE which overlaps a certain area of the semiconductor pattern in the third direction DR3.

The semiconductor pattern may be disposed on the buffer layer BFL. The semiconductor pattern may include a channel area CH, a first terminal TE1, and a second terminal TE2. The first terminal TE1 and the second terminal TE2 may be made conductive by a heat treatment (or doping with impurities). One of the first terminal TE1 and the second terminal TE2 may be a source electrode (or a source area), and the other one may be a drain electrode (or a drain area). The semiconductor pattern may include polycrystalline silicon, monocrystalline silicon, low-temperature polycrystalline silicon, amorphous silicon, or an oxide semiconductor. As another example, the semiconductor pattern may include first and second active layers disposed in different layers. In this case, the first active layer may include polycrystalline silicon, monocrystalline silicon, low-temperature polycrystalline silicon, and/or amorphous silicon, and the second active layer may include an oxide semiconductor.

The gate electrode GE of the transistor T may be disposed on the first gate insulating layer GI1. The gate electrode GE of the transistor T may be a second conductive layer disposed between the first gate insulating layer GI1 and the second gate insulating layer GI2. The gate electrode GE of the transistor T may overlap the channel area CH of the semiconductor pattern in the third direction DR3. The first gate insulating layer GI1 may electrically insulate the channel area CH of the semiconductor pattern and the gate electrode GE from each other.

The second conductive layer may include a first capacitor electrode CE1 of the capacitor C.

The second conductive layer including the gate electrode GE and the first capacitor electrode CE1 may have a single-layer structure or a multi-layer structure. The second gate insulating layer GI2 may be disposed on the second conductive layer.

The second capacitor electrode CE2 of the capacitor C may be disposed on the second gate insulating layer GI2. The second capacitor electrode CE2 may be a third conductive layer positioned between the second gate insulating layer GI2 and the interlayer insulating layer ILD. The second capacitor electrode CE2 may overlap the first capacitor electrode CE1 with the second gate insulating layer GI2 interposed therebetween, thus forming a capacitance. In the case where an overlapping surface area of the first capacitor electrode CE1 and the second capacitor electrode CE2 is relatively large, the capacitance of the capacitor C may be increased. The third conductive layer including the second capacitor electrode CE2 may have a single-layer structure or a multi-layer structure.

The interlayer insulating layer ILD may be disposed on the overall surface of the second capacitor electrode CE2.

The connection electrode CCE may be disposed on the interlayer insulating layer ILD. The connection electrode CCE may correspond to the fourth conductive layer positioned between the interlayer insulating layer ILD and the first via layer VIA1. The connection electrode CCE may be connected to the second terminal TE2 of the transistor T through respective contact holes of the interlayer insulating layer ILD, the second gate insulating layer GI2, and the first gate insulating layer GI1. The fourth conductive layer including the connection electrode CCE may have a single-layer structure or a multi-layer structure.

The first via layer VIA1 may be disposed on the fourth conductive layer. The first via layer VIA1 may be used to planarize the top of the fourth conductive layer.

The first passivation layer PAS1 may be disposed on the first via layer VIA1.

The anode connection line ACL and the power line VSL may be disposed on the first passivation layer PAS1. The anode connection line ACL and the power line VSL may correspond to the fifth conductive layer positioned between the first passivation layer PAS1 and the second via layer VIA2.

The anode connection line ACL may be electrically connected to the connection electrode CCE through respective contact holes of the first passivation layer PAS1 and the first via layer VIA1. The anode connection line ACL may be electrically connected to the second terminal TE2 of the transistor T through the connection electrode CCE.

The fifth conductive layer including the anode connection line ACL and the power line VSL may have a single-layer structure or a multi-layer structure.

The second via layer VIA2 may be disposed on the fifth conductive layer. The second via layer VIA2 may be used to planarize the top of the fifth conductive layer.

The second passivation layer PAS2 may be disposed on the second via layer VIA2.

The bridge pattern BRP may be disposed on the second passivation layer PAS2. The bridge pattern BRP may correspond to the sixth conductive layer positioned between the second passivation layer PAS2 and the third via layer VIA3. The bridge pattern BRP may be electrically connected to the anode connection line ACL through respective contact holes of the second passivation layer PAS2 and the second via layer VIA2. The bridge pattern BRP may be electrically connected to the transistor T through the anode connection line ACL and the connection electrode CCE. The sixth conductive layer including the bridge pattern BRP may have a single-layer structure or a multi-layer structure.

The third via layer VIA3 may be disposed on the overall surface of the sixth conductive layer. The third via layer VIA3 may be used to planarize the top of the sixth conductive layer.

The third passivation layer PAS3 may be disposed on the third via layer VIA3. The display element layer DPL may be disposed on the third passivation layer PAS3.

The display element layer DPL may include the first electrode PE1 and the second electrode PE2 disposed at positions that are spaced from each other, and the light emitting elements LD electrically connected to the first and second electrodes PE1 and PE2. Furthermore, the display element layer DPL may include the fourth via layer VIA4 and the fourth passivation layer PAS4.

The first electrode PE1 (referred to as “pixel electrode” or “anode”) and the second electrode PE2 (referred to as “common electrode” or “cathode”) may be positioned in the emission area EMA. The first electrode PE1 may have a double-layer structure including a first lower electrode PE1a and a first upper electrode PE1b, which are successively stacked. The second electrode PE2 may have a double-layer structure including a second lower electrode PE2a and a second upper electrode PE2b, which are successively stacked. The first lower electrode PE1a and the second lower electrode PE2a may include a suitable material selected from among the materials exemplified as the constituent materials of the first conductive layer. For example, the first lower electrode PE1a and the second lower electrode PE2a may include opaque conductive material. The first upper electrode PE1b and the second upper electrode PE2b may include transparent conductive material. The first upper electrode PE1b and the second upper electrode PE2b may include, for example, indium tin oxide.

The first lower electrode PE1a and the second lower electrode PE2a may correspond to a seventh conductive layer disposed on the third passivation layer PAS3. The first lower electrode PE1a and the second lower electrode PE2a may be disposed on the third passivation layer PAS3 at positions that are spaced from each other. Each of the first lower electrode PE1a and the second lower electrode PE2a may have a single-layer structure formed of one or more of molybdenum, aluminum, chromium, gold, titanium, nickel, neodymium, and/or copper, and/or an alloy thereof.

The first lower electrode PE1a may be electrically connected to the bridge pattern BRP through respective contact holes of the third passivation layer PAS3 and the third via layer VIA3. In one or more embodiments, in the case where the sixth conductive layer including the bridge pattern BRP is omitted, the first lower electrode PE1a may be directly connected to the anode connection line ACL through respective contact holes of the third passivation layer PAS3, the third via layer VIA3, the second passivation layer PAS2, and the second via layer VIA2.

The second lower electrode PE2a may be electrically connected to the power line VSL of the first pixel circuit layer PCL1 through respective contact holes of the third passivation layer PAS3, the third via layer VIA3, the second passivation layer PAS2, and the second via layer VIA2. Hence, a certain voltage of the power line VSL may be applied to the second lower electrode PE2a.

An eighth conductive layer may be disposed on the first lower electrode PE1a and the second lower electrode PE2a. The eighth conductive layer may include the first upper electrode PE1b and the second upper electrode PE2b. The first upper electrode PE1b may be disposed on the first lower electrode PE1a. The second upper electrode PE2b may be disposed on the second lower electrode PE2a. The eighth conductive layer may include transparent conductive material (TCO) such as ITO and/or IZO.

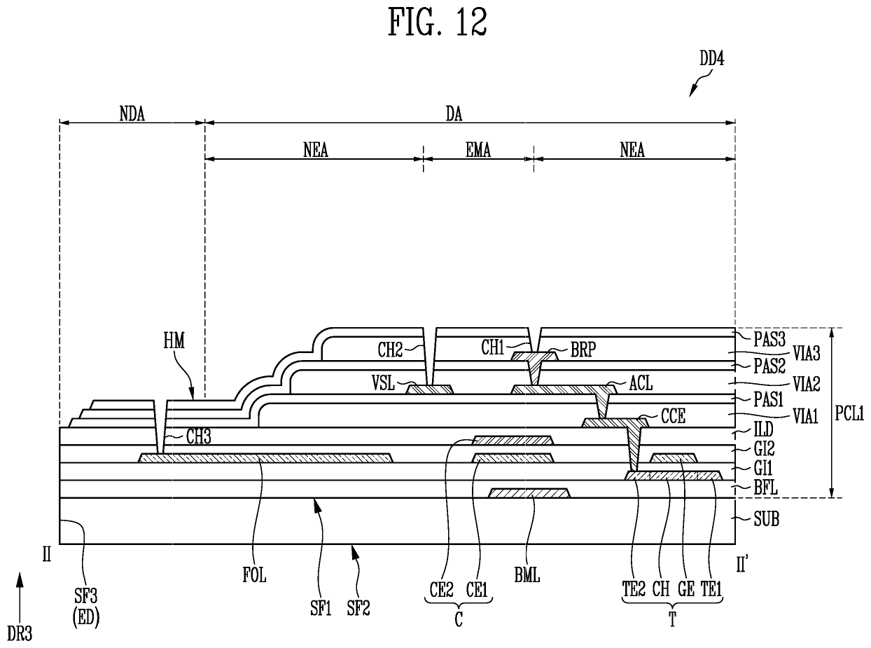

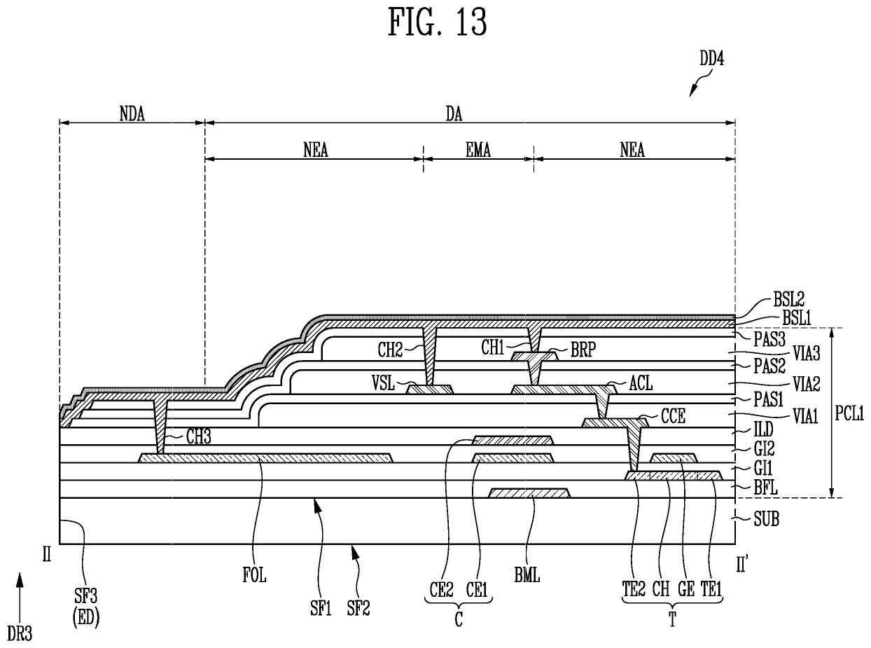

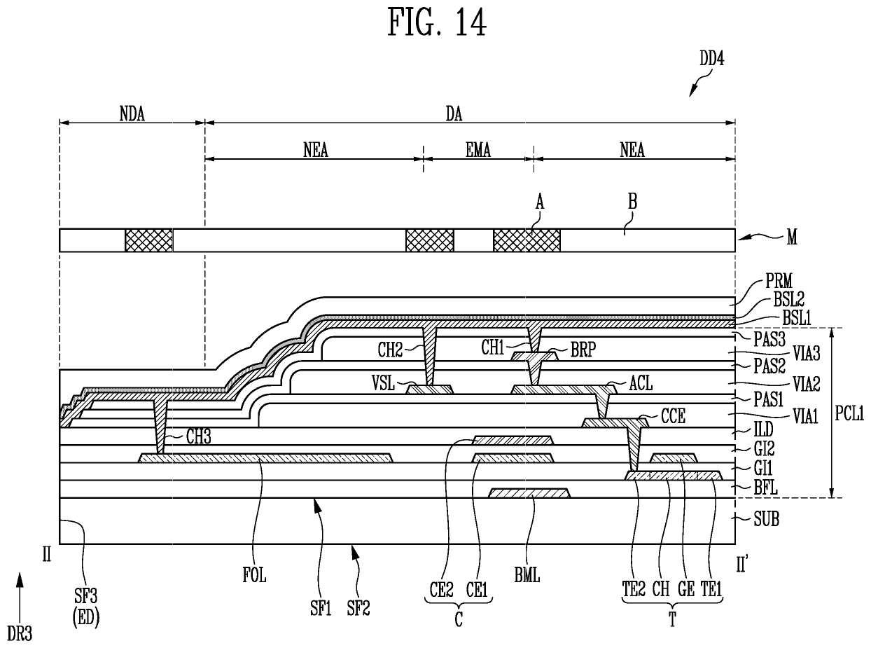

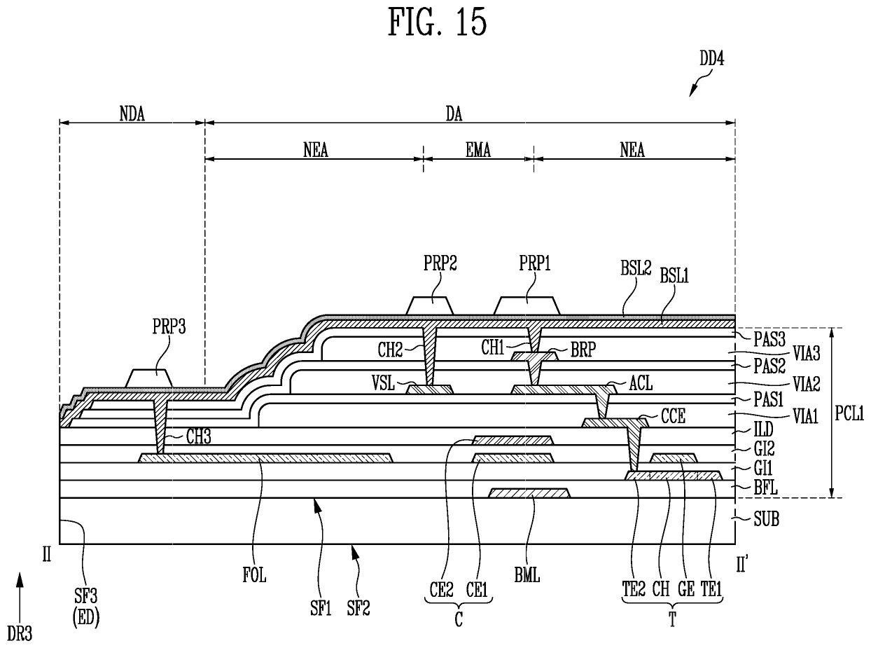

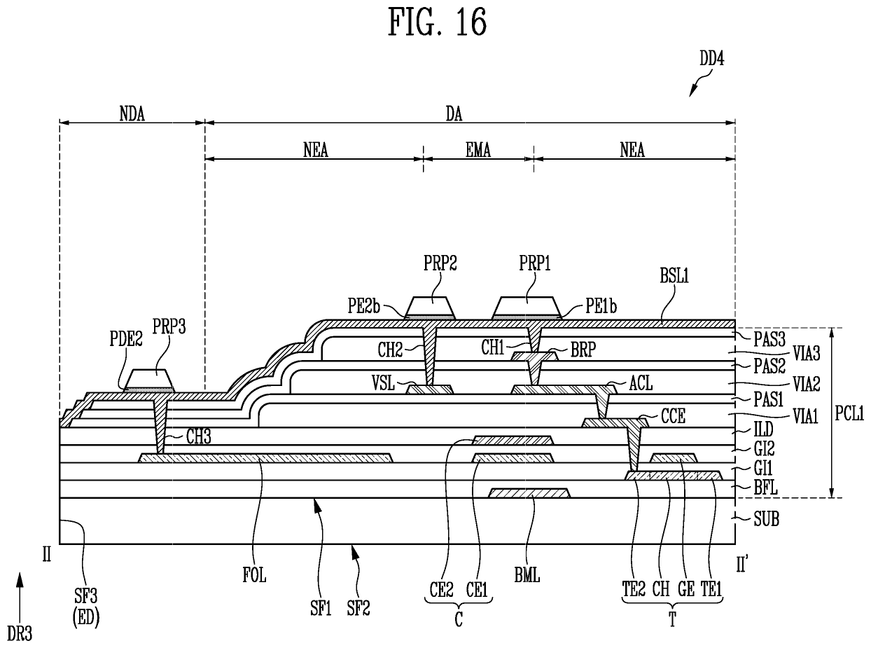

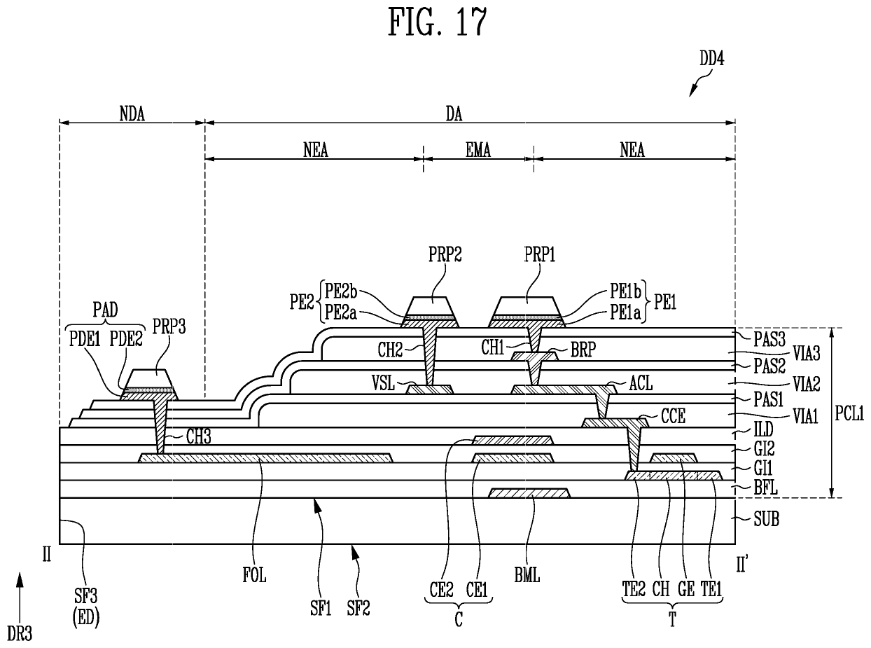

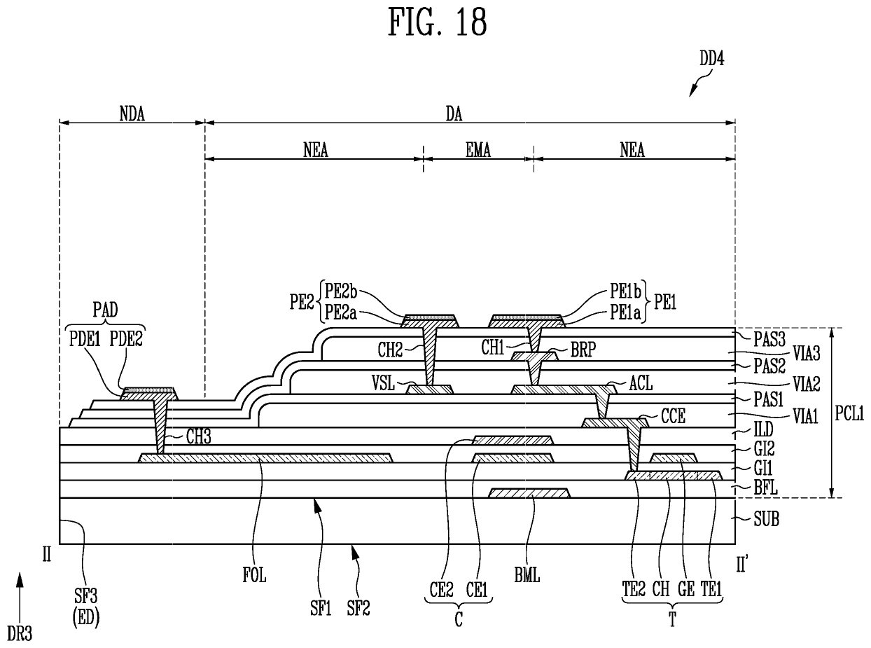

In one or more embodiments, the first lower electrode PE1a and the first upper electrode PE1b that constitute the first electrode PE1 may be concurrently (e.g., simultaneously) formed through the same process using the same mask. The second lower electrode PE2a and the second upper electrode PE2b that constitute the second electrode PE2 may be concurrently (e.g., simultaneously) formed through the same process using the same mask. For example, after the seventh conductive layer and the eighth conductive layer are successively deposited on the third passivation layer PAS3, a photolithography process using the same mask may be performed to concurrently (e.g., simultaneously) form the first electrode PE1 including the first lower electrode PE1a and the first upper electrode PE1b, and the second electrode PE2 including the second lower electrode PE2a and the second upper electrode PE2b. A method of fabricating the first electrode PE1 and the second electrode PE2 will be described below with reference to FIGS. 12 to 18.

The fourth via layer VIA4 may be disposed between two emission areas on the third passivation layer PAS3. A fourth passivation layer PAS4 may be on the fourth via layer VIA4, the first electrode PE1, and the second electrode PE2.

The fourth via layer VIA4 may include the same material as that of the first via layer VIA1, or may include suitable material selected from among materials exemplified as the constituent material of the first via layer VIA1. The fourth passivation layer PAS4 may planarize the top portions of the first electrode PE1 and the second electrode PE2. In one or more embodiments, the fourth via layer VIA4 may be partially open to expose each of the first electrode PE1 and the second electrode PE2. In one or more embodiments, the fourth via layer VIA4 may be disposed on the third passivation layer PAS3 without overlapping the first and second electrodes PE1 and PE2.

The fourth passivation layer PAS4 may be disposed on the fourth via layer VIA4. The fourth passivation layer PAS4 may include the same material as that of the first passivation layer PAS1, or may include suitable material selected from among the materials exemplified as the constituent material of the first passivation layer PAS1. In one or more embodiments, the fourth passivation layer PAS4 may be partially open to expose each of the first electrode PE1 and the second electrode PE2. The light emitting elements LD may be transferred onto the exposed top portions of the first electrode PE1 and the second electrode PE2, whereby the first and second electrodes PE1 and PE2 may be brought into contact with and electrically connected to the light emitting element LD. The first light emitting element LD1 may be transferred onto the top portions of the first electrode PE1 and the second electrode PE2 of the first sub-pixel SPX1. The second light emitting element LD2 may be transferred onto the top portions of the first electrode PE1 and the second electrode PE2 of the second sub-pixel SPX2. The third light emitting element LD3 may be transferred onto the top portions of the first electrode PE1 and the second electrode PE2 of the third sub-pixel SPX3.

The light emitting element LD may include a first contact electrode 15, a second contact electrode 16, a first semiconductor layer 11, an active layer 12, and a second semiconductor layer 13. In FIG. 8, it is illustrated that the light emitting element LD is a flip-chip type micro-light emitting diode, in which the first contact electrode 15 contacts the first electrode PE1, and the second contact electrode 16 contacts the second electrode PE2.

The light emitting element LD may have dimensions of several micrometers to several hundred micrometers in length in the vertical direction, length in the horizontal direction, and length in the thickness direction (or the third direction DR3) of the substrate SUB.

The light emitting element LD may be grown and formed on a semiconductor substrate such as a silicon wafer. The light emitting elements LD may be directly transferred from the silicon wafer onto the first electrode PE1 and the second electrode PE2 of the substrate SUB. The light emitting elements LD may be transferred onto the first electrode PE1 and the second electrode PE2 of the substrate SUB using either an electrostatic method using an electrostatic head or a stamp method using a transfer substrate made of an elastic polymer material such as PDMS or silicon.

The light emitting element LD may be a light emitting structure including a base substrate 1, a first semiconductor layer 11, an active layer 12, and a second semiconductor layer 13, a first contact electrode 15, and a second contact electrode 16. The light emitting element LD may include a first end, which contacts the first electrode PE1, and a second end, which contacts the second electrode P2. The second semiconductor layer 13 (or the first contact electrode 15) may be positioned on the first end. The first semiconductor layer 11 (or the second contact electrode 16) may be positioned on the second end.

The base substrate 1 may be a sapphire substrate, but the present disclosure is not limited thereto.

The first semiconductor layer 11 may be disposed on a certain surface of the base substrate 1. For example, the first semiconductor layer 11 may be disposed on a lower surface of the base substrate 1. The first semiconductor layer 11 may be formed of GaN doped with an n-type conductive dopant such as Si, Ge, or Sn.

The active layer 12 may be disposed on a first portion of a certain surface of the first semiconductor layer 11. The active layer 12 may include material having a single or multiple quantum well structure. In the case in which the active layer 12 includes material having a multiple quantum well structure, the active layer 12 may have a structure formed by alternately stacking a plurality of well layers and a plurality of barrier layers. Here, although the well layer may be formed of InGaN and the barrier layer may be formed of GaN or AlGaN, the present disclosure is not limited thereto. Alternatively, the active layer 12 may have a structure formed by alternately stacking semiconductor materials having large band gap energy and semiconductor materials having small band gap energy, and may include Group-Ill to V semiconductor materials depending on the wavelength band of light to be emitted.

The second semiconductor layer 13 may be disposed on a certain surface of the active layer 12. The second semiconductor layer 13 may be formed of GaN doped with a p-type conductive dopant such as Mg, Zn, Ca, Se, and/or Ba.

The first contact electrode 15 may be disposed on the second semiconductor layer 13, and the second contact electrode 16 may be disposed on a second portion of the certain surface of the first semiconductor layer 11. The second portion of the certain surface of the first semiconductor layer 11 on which the second contact electrode 16 is disposed may be disposed at a position that is spaced from the first portion of the certain surface of the first semiconductor 11 on which the active layer 12 is disposed. In one or more embodiments, the first contact electrode 15 and the second contact electrode 16 may be solder bumps. In one or more embodiments, the first contact electrode 15 and the second contact electrode 16 may be formed of eutectic metal such as tin (Sn), indium (In), zinc (Zn), lead (Pb), nickel (Ni), gold (Au), platinum (Pt), and/or copper (Cu), but are not limited thereto.

In one or more embodiments, the first contact electrode 15 and the first electrode PE1 may be combined with each other through a conductive adhesive component ACF. Furthermore, the second contact electrode 16 and the second electrode PE2 may be combined with each other through a conductive adhesive ACF.

The conductive adhesive ACF may include conductive particles PI formed in an adhesive film PF having adhesiveness. The conductive particles PI between the first contact electrode 15 and the first electrode PE1 may electrically connect the first contact electrode 15 and the first electrode PE1. The conductive particles PI between the second contact electrode 16 and the second electrode PE2 may electrically connect the second contact electrode 16 and the second electrode PE2. In this case, driving current may flow from the first electrode PE1 to the second electrode PE2 via the light emitting element LD. As a result, the light emitting element LD may emit light with luminance corresponding to the driving current. The first light emitting element LD1 of the first sub-pixel SPX1 may emit a first color of light with luminance corresponding to the driving current. The second light emitting element LD2 of the second sub-pixel SPX2 may emit a second color of light with luminance corresponding to the driving current. The third light emitting element LD3 of the third sub-pixel SPX3 may emit a third color of light with luminance corresponding to the driving current.

The second pixel circuit layer PCL2 may be disposed on the second surface SF2 of the substrate SUB. The second pixel circuit layer PCL2 may include rear patterns electrically connecting the transistor T to the external driver, and at least one rear insulating layers disposed between the rear patterns. For example, the rear insulating layers may include a fifth passivation layer PAS5, a fifth via layer VIA5, and a sixth passivation layer PAS6, which are successively stacked in a direction opposite to the third direction DR3.

The fifth passivation layer PAS5 may be positioned on the second surface SF2 of the substrate SUB, thus protecting the second surface SF2 of the substrate SUB. The fifth passivation layer PAS5 may be an inorganic insulating layer including inorganic material. The fifth passivation layer PAS5 may include at least one of silicon nitride (SiNₓ), silicon oxide (SiOₓ), silicon oxynitride (SiOₓN_{y}), and/or aluminum oxide (AlOₓ).

The fifth via layer VIA5 may be disposed on the fifth passivation layer PAS5. The fifth via layer VIA5 may be an organic insulating layer including an organic material. The fifth via layer VIA5 may include at least one from among polyacrylates resin, epoxy resin, phenolic resin, polyamides resin, polyimides resin, unsaturated polyesters resin, poly-phenylen ethers resin, poly-phenylene sulfides resin, and/or benzocyclobutene resin. The fifth via layer VIA5 may planarize the second surface SF2 of the substrate SUB.

The sixth passivation layer PAS6 may be disposed on the fifth via layer VIA5, thus protecting the fifth via layer VIA5. The sixth passivation layer PAS6 may include a suitable material from among the materials exemplified as the constituent materials of the fifth passivation layer PAS5.

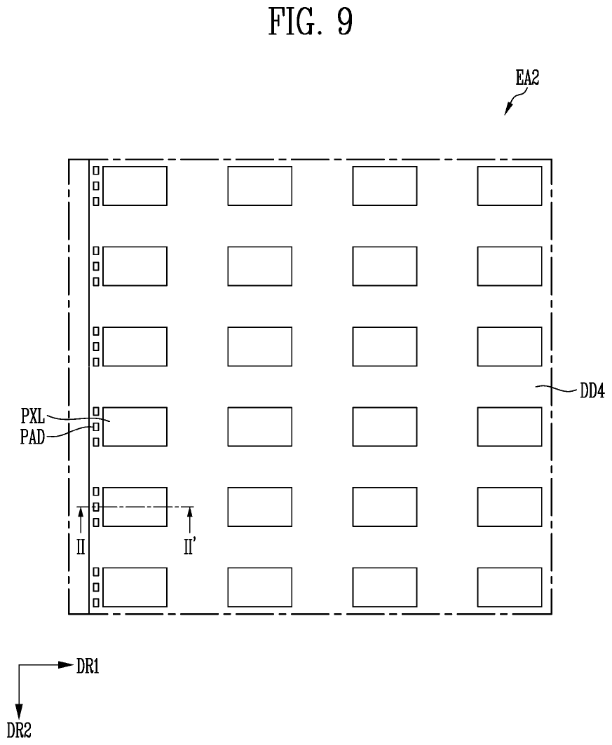

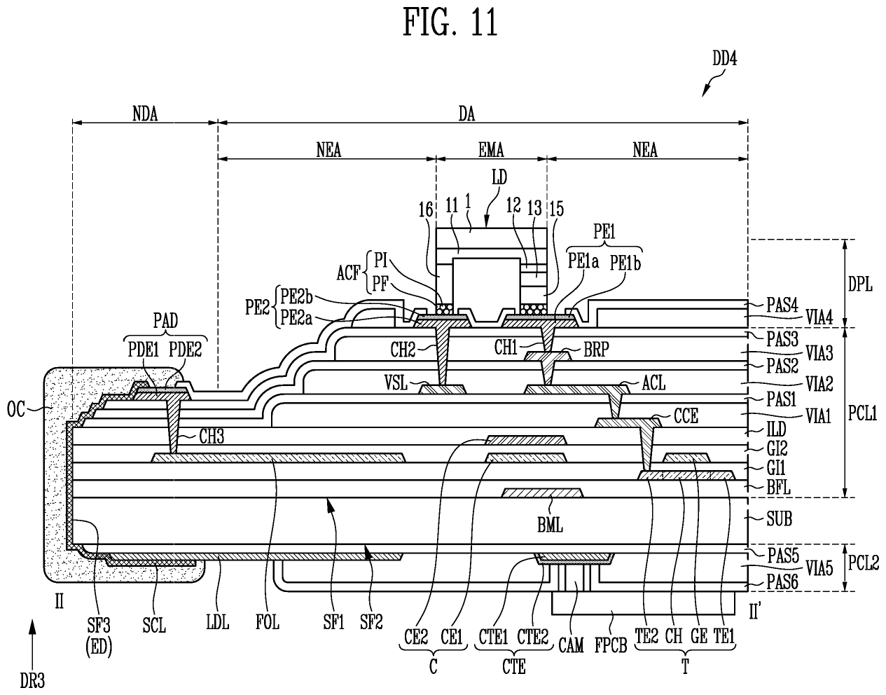

FIG. 9 is a schematic enlarged view showing a portion EA2 of FIG. 2. FIGS. 10 and 11 are schematic cross-sectional views taken along the line II-II′ of FIG. 9.

In FIG. 9, it is illustrated pixels PXL and pad electrodes PAD disposed on the left side of the fourth display device DD4.

FIG. 11 illustrates a modification of the embodiment of FIG. 10 with regard to components disposed on the side connection line SCL.

The description with reference to FIGS. 9 to 11 will be focused on differences from the above-mentioned embodiments so as to avoid redundant description.

Referring to FIGS. 2, and 9 to 11, the pad electrodes PAD may be disposed along a left edge of the fourth display device DD4. In the case where signal lines of the fourth display device DD4, e.g., data lines, extend in a direction opposite to the first direction DR1, the pad electrodes PAD may be disposed along the left edge and right edge of the fourth display device DD4.

Each of the pad electrodes PAD may be electrically connected to the data lines positioned in the display area DA through a fan-out line FOL positioned in the non-display area NDA. Furthermore, each of the pad electrodes PAD may be electrically connected to the side connection line SCL. Each of the pad electrodes PAD may supply a voltage or signal received from the side connection line SCL to the fanout line FOL. The fanout line FOL may be positioned on the first gate insulating layer GI1 and covered with the second gate insulating layer GI2. The fanout line FOL may correspond to the second conductive layer.

Each of the pad electrodes PAD may be disposed on the third passivation layer PAS3 in the non-display area NDA. The pad electrodes PAD may be exposed without being covered with the fourth passivation layer PAS4. Each of the pad electrodes PAD may be electrically connected to the fanout line FOL through a third contact hole CH3 passing through the third passivation layer PAS3, the second passivation layer PAS2, the first passivation layer PAS1, the interlayer insulating layer ILD, and the second gate insulating layer GI2. The first via layer VIA1, the second via layer VIA2, the third via layer VIA3, and the fourth via layer VIA4, which are formed of organic layers including organic material, may not be positioned in the non-display area NDA where the pad electrodes PAD are disposed.

In one or more embodiments, each of the pad electrodes PAD may include a first pad electrode PDE1 and a second pad electrode PDE2. Therefore, the first pad electrode PDE1 may include the same material as the first and second lower electrodes PE1a and PE2a. The second pad electrode PDE2 may include the same material as the first and second upper electrodes PE1b and PE2b. For example, the first pad electrodes PDE1 and the first and second lower electrodes PE1a and PE2a may include opaque conductive material. The second pad electrode PDE2 and the first and second upper electrodes PE1b and PE2b may include transparent conductive material. In one or more embodiments, the first lower electrode PE1a may be electrically connected to the bridge pattern BRP through a first contact hole CH1 passing through the third passivation layer PAS3 and the third via layer VIA3. The second lower electrode PE2a may be electrically connected to the power line VSL through a second contact hole CH2 of the third passivation layer PAS3, the third via layer VIA3, the second passivation layer PAS2, and the second via layer VIA2.

The second pad electrode PDE2 may be directly disposed on the first pad electrode PDE1, and may have the same profile (or shape) as the first pad electrode PDE1. For example, opposite side surfaces of the first pad electrodes PDE1 may have an inclination angle 61 (or a slope), which is substantially similar to or the same as an inclination angle 62 (or a slope) of opposite side surfaces of the second pad electrode PDE2. In this case, the opposite side surfaces of the first pad electrode PDE1 and the opposite side surfaces of the second pad electrode PDE2 may correspond (or match) with each other. In other words, the opposite side surfaces of the first pad electrode PDE1 may be positioned on the same lines as the opposite side surfaces of the second pad electrode PDE2.

Each pad electrode PAD including the first pad electrode PDE1 and the second pad electrode PDE2 may be electrically connected to the lead line LDL through the side connection line SCL.

An intermediate electrode CTE may be disposed on the second pixel circuit layer PCL2 positioned on the second surface SF2 of the substrate SUB.

The intermediate electrode CTE may be disposed on the fifth passivation layer PAS5. The intermediate electrode CTE may supply a voltage or signal received from a flexible film FPCB to the side connection line SCL through the lead line LDL. The intermediate electrode CTE may be electrically connected to the flexible film FPCB using a conductor CAM. The intermediate electrode CTE may be one of the rear patterns disposed in the second pixel circuit layer PCL2.

The intermediate electrode CTE may include a first intermediate electrode CTE1 and a second intermediate electrode CTE2. The first intermediate electrode CTE1 may be disposed a certain surface (or lower surface) of the fifth passivation layer PAS5. The first intermediate electrode CTE1 may have a single-layer structure formed of one or more of molybdenum, aluminum, chromium, gold, titanium, nickel, neodymium, and/or copper, and/or an alloy thereof. The second intermediate electrode CTE2 may include transparent conductive material such as ITO and/or IZO.

The lead line LDL may be disposed on a certain surface of the fifth passivation layer PAS5. The lead line LDL may be formed in the same layer as the first intermediate electrode CTE1 using the same material. The lead line LDL may supply a voltage or signal received from the intermediate electrode CTE to the side connection line SCL.

The side connection line SCL may be disposed on the first surface SF1, the second surface SF2, and the side surface SF3 (or the edge area ED) of the substrate SUB. The first end of the side connection line SCL may be electrically and/or physically connected to each pad electrode PAD. The second end of the side connection line SCL may be electrically and/or physically connected to the lead line LDL. The side connection line SCL may be positioned in the non-display area NDA, and may enclose a side surface of each of the substrate SUB, the buffer layer BFL, the first and second gate insulating layers GI1 and GI2, the interlayer insulating layer ILD, the first to third passivation layers PAS1, PAS2, and PAS3, and the fifth passivation layer PAS5.

In one or more embodiments, an overcoat layer OC may be disposed on the side connection line SCL, as illustrated in FIG. 11. The overcoat layer OC may cover the side connection line SCL. The overcoat layer OC may cover the entirety of the side connection line SCL to prevent the side connection line SCL from being corroded. The overcoat layer OC may be formed of an inorganic insulating layer including an inorganic material or an organic insulating layer including an organic material. The overcoat layer OC may be disposed on each pad electrode PAD electrically connected to the side connection line SCL, thus protecting the pad electrode PAD. The overcoat layer OC may be disposed on each pad electrode PAD and the side connection line SCL, and may function as a protective component for protecting the pad electrode PAD and the side connection line SCL.

The fifth via layer VIA5 may be disposed on the lead line LDL, the intermediate electrode CTE, and the fifth passivation layer PAS5. The fifth via layer VIA5 may be partially open to expose a portion of each of the lead line LDL and the intermediate electrode CTE.

The sixth passivation layer PAS6 may be disposed on the fifth via layer VIA5. The sixth passivation layer PAS6 may be partially open to expose a portion of each of the lead line LDL and the intermediate electrode CTE.

The flexible film FPCB may be disposed on a lower surface of the sixth passivation layer PAS6. The flexible film FPCB may be electrically connected, by the conductor CAM, to the intermediate electrode CTE through a contact hole passing through the sixth passivation layer PAS6 and the fifth via layer VIA5.

A first side of the flexible film FPCB may supply a voltage or signal to each pad electrode PAD disposed on the first surface SF1 of the substrate SUB through the intermediate electrode CTE, the lead line LDL, and the side connection line SCL. A second side of the flexible film FPCB may be connected to a source circuit board under the substrate SUB. The flexible film FPCB may transmit a signal from a display driver to the fourth device DD4.

The conductor CAM may attach the flexible film FPCB to the lower surface of the intermediate electrode CTE. For example, the conductor CAM may be an anisotropic conductive film or anisotropic conductive paste. In the case where the conductor CAM includes an anisotropic conductive film, the conductor CAM may have conductivity in an area where the intermediate electrode CTE and the flexible film FPCB contact each other, and may electrically connect the flexible film FPCB to the intermediate electrode CTE.

The fourth display device DD4 may include the flexible film FPCB disposed on the second surface SF2 of the substrate SUB, the pad electrodes PAD disposed on the first surface SF1 of the substrate SUB, and the intermediate electrode CTE, the lead line LDL, and the side connection line SCL, which electrically connect the flexible film FPCB and the pad electrode PAD, thus reducing or minimizing the surface area of the non-display area NDA.

Hereinafter, a method of fabricating each pad electrode PAD positioned in the non-display area NDA and the first and second electrodes PE1 and PE2 positioned in the display area DA will be described.

FIGS. 12 to 18 are schematic cross-sectional views illustrating a method of fabricating the pad electrode PAD, the first electrode PE1, and the second electrode PE2 of FIG. 10.

The description of an embodiment of FIGS. 12 to 18 will be focused on differences from the above-mentioned embodiments so as to avoid redundant description.

Referring to FIGS. 10 to 12, the first pixel circuit layer PCL1 may be formed on the first surface SF1 of the substrate SUB.

In the display area DA, each of the second via layer VIA2, the second passivation layer PAS2, the third via layer VIA3, and the third passivation layer PAS3 of the first pixel circuit layer PCL1 may be partially open to include the second contact hole CH2 through which a certain area of the power line VSL is exposed. Furthermore, in the display area DA, each of the third via layer VIA3 and the third passivation layer PAS3 of the first pixel circuit layer PCL1 may be partially open to include the first contact hole CH1 through which a certain area of the bridge pattern BRP is exposed.

In the non-display area NDA, each of the third passivation layer PAS3, the second passivation layer PAS2, the first passivation layer PAS1, the interlayer insulating layer ILD, and the second gate insulating layer GI2 of the first pixel circuit layer PCL1 may be partially open to include the third contact hole CH3 through which a certain area of the fanout line FOL is exposed.

In the non-display area NDA, there is positioned a stepped portion HM. The stepped portion HM may be formed in the non-display area NDA by a difference in thickness (or height) between the display area DA and the non-display area NDA by removing some of the components positioned in the display area DA, for example, the first via layer VIA1, the second via layer VIA2, and the third via layer VIA3 from the non-display area NDA.

The stepped portion HM may be positioned adjacent to the pad electrode PAD to be formed through a subsequent process.

Referring to FIGS. 10, 12, and 13, the first base layer BSL1 is formed on the overall surface of the third passivation layer PAS3 in the non-display area NDA and the display area DA. Subsequently, the second base layer BSL2 is formed on the first base layer BSL1.

The first base layer BSL1 may provide a base material for the first pad electrode PDE1, the first lower electrode PE1a, and the second lower electrode PE2a, as the seventh conductive layer disposed on the third passivation layer PAS3. The first base layer BSL1 may contact the power line VSL through the second contact hole CH2, may contact the bridge pattern BRP through the first contact hole CH1, and may contact the fanout line FOL through the third contact hole CH3.

The second base layer BSL2 may provide a base material for the second pad electrode PDE2, the first upper electrode PE1b, and the second upper electrode PE2b, as the eighth conductive layer disposed on the first base layer BSL1.

The first base layer BSL1 may include opaque conductive material. The second base layer BSL2 may include transparent conductive material.

Referring to FIGS. 10 and 12 to 14, a photosensitive material layer PRM is deposited on the second base layer BSL2 by front-side deposition, and a mask M is disposed over the photosensitive material layer PRM.

The mask M may include a plurality of areas A and B having different light transmissivities. For example, the mask M may include a first area A and a second area B, which are divided according to the light transmissivity. The first area A may be a blocking area, which completely block light. The second area B may be a transmission area, which allows light to pass therethrough. However, the present disclosure is not limited to the aforementioned example. In one or more embodiments, the first area A may allow light to partially pass therethrough, with light transmissivity that is markedly less than the light transmissivity (or the light transmission ratio) of the second area B.

The mask M may be disposed over the photosensitive material layer PRM such that the first area A corresponds to a formation position of each of the pad electrode PAD and the first and second electrodes PE1 and PE2, and the second area B corresponds to a remaining area other than the formation position.

The first area A may block incident light from the outside, thus preventing the light from reaching the photosensitive material layer PRM that overlaps both an area where the first and second electrodes PE1 and PE2 are needed to be formed in the display area DA, and an area where the pad electrode PAD is needed to be formed in the non-display area NDA.

The second area B allows incident light from the outside to pass therethrough, thus allowing the light from reaching the photosensitive material layer PRM that overlaps both an area where the first and second electrodes PE1 and PE2 are not formed in the display area DA, and an area where the pad electrode PAD is not formed in the non-display area NDA.

The photosensitive material layer PRM may include positive photosensitive material or negative photosensitive material. For example, in the case where the photosensitive material layer PRM includes positive photosensitive material, an exposed area of the photosensitive material layer PRM may have a property of being easily dissolved in a developing solution, and an unexposed area of the photosensitive material layer PRM may have a property of being not easily dissolved in a developing solution. As another example, in the case where the photosensitive material layer PRM includes negative photosensitive material, the exposed area of the photosensitive material layer PRM may have a property of being not easily dissolved in a developing solution, and the unexposed area of the photosensitive material layer PRM may have a property of being easily dissolved in a developing solution.

Depending on the chemical change characteristics of the exposed and unexposed areas of the photosensitive material layer PRM, certain areas may be retained while the other areas may be selectively removed using a certain developing solution. In one or more embodiments, the photosensitive material layer PRM may include positive photosensitive material.

Referring to FIGS. 10, and 12 to 15, a first photosensitive pattern PRP1, a second photosensitive pattern PRP2, and a third photosensitive pattern PRP3 are formed by performing an exposure process and a development process using the mask M.

The first, second, and third photosensitive patterns PRP1, PRP2, and PRP3 may be a certain area of the photosensitive material layer PRM that corresponds to the first area A of the mask M. The first photosensitive pattern PRP1 may be disposed on the second base layer BSL2 at a position at which the first electrode PE1 is formed. The second photosensitive pattern PRP2 may be disposed on the second base layer BSL2 at a position at which the second electrode PE2 is formed. The third photosensitive pattern PRP3 may be disposed on the second base layer BSL2 at a position at which the pad electrode PAD is formed.

After the aforementioned exposure process and the development process are performed, portions of the second base layer BSL2 that do not correspond to the first, second, and third photosensitive patterns PRP1, PRP2, and PRP3 may be exposed.

Referring to FIGS. 10 and 12 to 16, the exposed portions of the second base layer BSL2 are removed by performing a first etching process using the first, second, and third photosensitive patterns PRP1, PRP2, and PRP3 as an etching mask, whereby a second layer is formed. The second layer may include the first upper electrode PE1b, the second upper electrode PE2b, and the second pad PDE2.

The first upper electrode PE1b may be a certain area of the second base layer BSL2 that remains under the first photosensitive pattern PRP1. The second upper electrode PE2b may be a certain area of the second base layer BSL2 that remains under the second photosensitive pattern PRP2. The second pad electrode PDE2 may be a certain area of the second base layer BSL2 that remains under the third photosensitive pattern PRP3.

In one or more embodiments, the first etching process may be a wet etching process. By adjusting wet etching conditions or the like, the first upper electrode PE1b may be formed to have a profile substantially similar or identical to that of the first photosensitive pattern PRP1, the second upper electrode PE2b may be formed to have a profile substantially similar or identical to that of the second photosensitive pattern PRP2, and the second pad electrode PDE2 may be formed to have a profile substantially similar or identical to that of the third photosensitive pattern PRP3.

The portions of the second base layer BSL2 that are exposed to the outside without corresponding to the first, second, and third photosensitive patterns PRP1, PRP2, and PRP3 may be completely removed through the aforementioned first process, thus allowing the first base layer BSL1 disposed thereunder to be exposed to the outside. Because the portions of the second base layer BSL2 that are exposed to the outside without corresponding to the photosensitive patterns are completely removed through the first etching process, the second base layer BSL2 may also not remain in the stepped portion HM described with reference to FIG. 12. Hence, a short defect between adjacent pad electrodes may be prevented from occurring due to the second base layer BSL2 remaining in the stepped portion HM.

Referring to FIGS. 10 and 12 to 17, a second etching process using the photosensitive patterns and the second layers disposed thereunder as an etching mask may be performed to remove exposed portions of the first base layer BSL1, thus forming a first layer. The first layer may include the first lower electrode PE1a, the second lower electrode PE2a, and the first pad PDE1.

The first lower electrode PE1a may be a certain area of the first base layer BSL1 that remains under the first photosensitive pattern PRP1 and the first upper electrode PE1b. The second lower electrode PE2a may be a certain area of the first base layer BSL1 that remains under the second photosensitive pattern PRP2 and the second upper electrode PE2b. The first pad electrode PDE1 may be a certain area of the first base layer BSL1 that remains under the third photosensitive pattern PRP3 and the second pad electrode PDE2.

In one or more embodiments, the second etching process may be a dry etching process.

The first lower electrode PE1a may have a profile substantially similar or identical to that of the first upper electrode PE1b disposed thereover. For example, opposite side surfaces of the first lower electrode PE1a may have an inclination angle substantially similar or identical to that of opposite side surfaces of the first upper electrode PE1b. In this case, the opposite side surfaces of the first lower electrode PE1a may be positioned on the same lines as the opposite side surfaces of the first upper electrode PE1b.

The second lower electrode PE2a may have a profile substantially similar or identical to that of the second upper electrode PE2b disposed thereover. For example, opposite side surfaces of the second lower electrode PE2a may have an inclination angle substantially similar or identical to that of opposite side surfaces of the second upper electrode PE2b. In this case, the opposite side surfaces of the second lower electrode PE2a may be positioned on the same lines as the opposite side surfaces of the second upper electrode PE2b.

The first pad electrode PDE1 may have a profile substantially similar or identical to that of the second pad electrode PDE2 disposed thereover. For example, opposite side surfaces of the first pad electrode PDE1 may have an inclination angle substantially similar or identical to that of opposite side surfaces of the second pad electrode PDE2. In this case, the opposite side surfaces of the first pad electrode PDE1 may be positioned on the same lines as the opposite side surfaces of the second pad electrode PDE2.

After the aforementioned second etching process is performed, the exposed portions of the first base layer BSL1 is removed to allow the third passivation layer PAS3 disposed thereunder to be exposed to the outside.

Referring to FIGS. 10 and 12 to 18, a strip process is performed to remove the first, second, and third photosensitive patterns PRP1, PRP2, and PRP3, thus allowing the first upper electrode PE1b, the second upper electrode PE2b, and the second pad electrode PDE2 to be exposed to the outside.

The first lower electrode PE1a (e.g., the first layer) and the first upper electrode PE1b (e.g., the second layer) that have the same profile and are successively stacked on the third passivation layer PAS3 in the third direction DR3 may constitute the first electrode PE1.

The second lower electrode PE2a (e.g., the first layer) and the second upper electrode PE2b (e.g., the second layer) that have the same profile and are successively stacked on the third passivation layer PAS3 in the third direction DR3 may constitute the second electrode PE2.

The first pad electrode PDE1 (e.g., the first layer) and the second pad electrode PDE2 (e.g., the second layer) that have the same profile and are successively stacked on the third passivation layer PAS3 in the third direction DR3 may constitute the pad electrode PAD.

According to the aforementioned embodiment, the first electrode PE1, the second electrode PE2, and the pad electrode PAD each having a double-layer structure including the first layer and the second layer, which have the same profile and are formed of different conductive materials, may be formed through a photolithography process using one mask M. Therefore, the fabrication efficiency of the fourth display device DD4 (or the display device DD) may be enhanced.

Furthermore, according to the aforementioned embodiment, the portions of the second base layer BSL2 that are exposed to the outside without corresponding to the first, second, and the third photosensitive patterns PRP1, PRP2, and PRP3 may be completely removed through the first etching process. Hence, the second base layer BSL2 may not remain on the stepped portion HM of the non-display area NDA. If the first layer (e.g., the first and second lower electrodes PE1a and PE2a and the first pad electrode PDE1) is formed using a first mask and the second layer (e.g., the first and second upper electrodes PE1b and PE2b and the second pad electrode PDE2) is formed using a second mask separately provided from the first mask, a portion of the transparent conductive material layer corresponding to a base material for the second layer may remain on the stepped portion (refer to “HM” of FIG. 12) due to a difference in thickness between the display area DA and the non-display area NDA. In this case, there is a possibility of short defects occurring due to electrical connection between adjacent pad electrodes (PAD) caused by the transparent conductive material layer remaining on the stepped portion HM. In the aforementioned embodiment, during the photolithography process using a single mask M, the first etching (or wet etching) is performed to completely remove the exposed portions of the second base layer BSL2 that are exposed to the outside without corresponding to the photosensitive patterns and thus form the second layer (e.g., the first and second upper electrodes PE1b and PE2b and the second pad electrode PDE2), and thereafter the second etching (or dry etching) is performed using the second layer as an etching mask to form first layer (e.g., the first and second lower electrode PE1a and PE2a and the first pad electrode PDE1) under the second layer. As a result, defects that could occur due to the transparent conductive material layer remaining on the stepped portion HM may be prevented. Accordingly, the reliability of the fourth display device DD4 (or the display device DD) may be enhanced.

In accordance with one or more embodiments, residues of transparent conductive material between a pad electrode and a stepped portion of a via layer in a non-display area (or a pad area) may be reduced or prevented, whereby short defects caused by electrical connection between adjacent pad electrodes may be mitigated or prevented. As a result, the reliability of the display device can be enhanced.

In accordance with one or more embodiments, a first pad electrode and a second pad electrode that constitute each pad electrode may be formed using the same mask, thus making it possible to reduce the number of masks. Accordingly, the fabrication efficiency of the display device may be improved.

The effects of the present disclosure are not limited by the foregoing, and other various effects are anticipated herein.

While various embodiments have been described above, those skilled in the art will appreciate that various modifications, additions and substitutions are possible, without departing from the spirit and scope of the present disclosure.

Therefore, the embodiments disclosed in this specification are only for illustrative purposes rather than limiting the technical spirit of the present disclosure. The scope of the present disclosure must be defined by the accompanying claims and their equivalents.

What is claimed is:

1. A display device, comprising:
a substrate having a display area and a non-display area, and including a first surface and a second surface facing away from each other in a thickness direction of the substrate and a side surface connecting the first surface and the second surface;
a light emitting element on the first surface of the substrate in the display area;
a pad electrode on the first surface of the substrate in the non-display area;
an intermediate electrode on the second surface of the substrate in the display area; and
a side connection line on the side surface, and electrically connected to each of the pad electrode and the intermediate electrode,
wherein the pad electrode comprises a first pad electrode and a second pad electrode that are successively stacked, and
wherein opposite side surfaces of the second pad electrode have inclination angles that are same as inclination angles of opposite side surfaces of the first pad electrode.

2. The display device according to claim 1, wherein the first pad electrode comprises an opaque conductive material, and the second pad electrode comprises a transparent conductive material.

3. The display device according to claim 1, further comprising:
a first pixel circuit layer on the first surface of the substrate;
a display element layer on the first pixel circuit layer; and
a second pixel circuit layer on the second surface of the substrate,
wherein the pad electrode is on the first pixel circuit layer.

4. The display device according to claim 3, wherein the display element layer comprises:
a first electrode and a second electrode on the first pixel circuit layer in the display area and spaced from each other; and
the light emitting element electrically connected to the first electrode and the second electrode.

5. The display device according to claim 4,
wherein each of the first electrode and the second electrode comprises a lower electrode and an upper electrode that are successively stacked, and
wherein the lower electrode is in a same layer as the first pad electrode, and the upper electrode is in a same layer as the second pad electrode.

6. The display device according to claim 5, wherein the lower electrode comprises a same material as the first pad electrode, and the upper electrode comprises a same material as the second pad electrode.

7. The display device according to claim 5, wherein opposite side surfaces of the upper electrodes of the first electrode and the second electrode have inclination angles that are same as inclination angles of opposite side surfaces of the corresponding lower electrodes of the first electrode and the second electrode.

8. The display device according to claim 4, wherein the display element layer further comprises an anisotropic conductive film located between each of the first and second electrodes and the light emitting element, and configured to electrically connect the first electrode to one side of the light emitting element, and electrically connect the second electrode to a remaining side of the light emitting element.

9. The display device according to claim 3, wherein the first pixel circuit layer further comprises:
a transistor electrically connected to the light emitting element; and
a light blocking pattern between the substrate and a semiconductor pattern of the transistor.

10. The display device according to claim 3, wherein the second pixel circuit layer comprises:
a first insulating layer on the second surface of the substrate;
a connection electrode on the first insulating layer;
a via layer on the first insulating layer and the connection electrode, and allowing a portion of the connection electrode to be exposed; and
a second insulating layer on the via layer.

11. The display device according to claim 10,
wherein the connection electrode comprises a first connection electrode and a second connection electrode stacked successively from the first insulating layer, and
wherein the first connection electrode comprises an opaque conductive material, and the second connection electrode comprises a transparent conductive material.

12. The display device according to claim 1, further comprising an overcoat layer on the side connection line and the pad electrode, and covering the side connection line and the pad electrode.

13. The display device according to claim 1, wherein the light emitting element comprises a micro light emitting diode.

14. A method of fabricating a display device, comprising:
forming a first pixel circuit layer comprising a front pattern on a first surface of a substrate;
forming, on the first pixel circuit layer, a pad electrode, a first electrode, and a second electrode that are spaced from each other;
forming a second pixel circuit layer comprising a rear pattern on a second surface of the substrate;
forming a side connection line on a side surface of the substrate; and
transferring a light emitting element on the first electrode and the second electrode, and electrically connecting the light emitting element to each of the first and the second electrodes,
wherein the pad electrode comprises a first pad electrode and a second pad electrode stacked successively on the first pixel circuit layer, and
wherein opposite side surfaces of the second pad electrode have inclination angles that are same as inclination angles of opposite side surfaces of the first pad electrode.

15. The method according to claim 14, wherein forming the pad electrode comprises:
applying a first base layer for the first pad electrode on the first pixel circuit layer, applying a second base layer for the second pad electrode on the first base layer, and applying a photosensitive material layer on the second base layer;
disposing a mask over the photosensitive material layer and forming a photosensitive pattern covering one area of the second base layer and exposing a remaining area of the second base layer;
performing a first etching process to remove the exposed remaining area of the second base layer and exposing the first base layer located thereunder;
performing a second etching process and removing the exposed first base layer; and
removing the photosensitive pattern and exposing the one area of the second base layer under the photosensitive pattern and one area of the first base layer under the one area of the second base layer.

16. The method according to claim 15, wherein the first etching process comprises a wet etching process, and the second etching process comprises a dry etching process.

17. The method according to claim 15,
wherein the first base layer comprises an opaque conductive material, and the second base layer comprises a transparent conductive material, and
wherein the one area of the second base layer comprises the second pad electrode, and the one area of the first base layer comprises the first pad electrode.

18. The method according to claim 17,
wherein each of the first electrode and the second electrode comprises a lower electrode and an upper electrode successively stacked on the first pixel circuit layer, and
wherein the lower electrode is formed through a same process as the first pad electrode, and the upper electrode is formed through a same process as the second pad electrode.

19. The method according to claim 18, wherein opposite side surfaces of the upper electrodes of the first electrode and the second electrode have inclination angles that are same as inclination angles of opposite side surfaces of the corresponding lower electrodes of the first electrode and the second electrode.

20. The method according to claim 14, wherein the light emitting element comprises a micro light emitting diode.
